(19) United States
(12) Patent Application Publication
(10) Pub. No.: US 2016/0351755 A1
(43) Pub. Date: Dec. 1, 2016

(54) LIGHT EMITTING DEVICE PACKAGE AND METHOD OF MANUFACTURING THE SAME

(71) Applicant: Samsung Electronics Co., Ltd., Suwon-si (KR)

(72) Inventors: Dong Kuk LEE, Suwon-si (KR); Yong Min KWON, Seoul (KR); Hyung Kun KIM, Suwon-si (KR); Dae Yeop HAN, Incheon (KR)

(21) Appl. No.: 15/166,254

(22) Filed: May 26, 2016

(30) Foreign Application Priority Data
May 27, 2015 (KR) 10-2015-0074243

(51) Int. Cl. H01L 33/46; H01L 33/00; H01L 33/38; H01L 33/06; H01L 33/32

(52) U.S. Cl. CPC H01L 33/46; H01L 33/06; H01L 33/32; H01L 33/382; H01L 33/007; H01L 2933/0025; H01L 2933/0016

(57) ABSTRACT

In one embodiment, a light emitting device package includes a light emitting device including a substrate and a light emitting structure including a first conductivity type semiconductor layer, an active layer, and a second conductivity type semiconductor layer, stacked on the substrate; a reflective conductive layer provided on the light emitting structure; and a first electrode and a second electrode overlying the reflective conductive layer separated from each other in a first region. The first electrode and the second electrode are electrically insulated from the reflective metal layer and penetrate through the reflective metal layer to be electrically connected to the first conductivity type semiconductor layer and the second conductivity type semiconductor layer, respectively.

### CROSS-REFERENCE TO RELATED APPLICATION

This application claims the priority and benefit of Korean Patent Application No. 10-2015-0074243 filed on May 27, 2015, with the Korean Intellectual Property Office, the disclosure of which is incorporated herein by reference.

### BACKGROUND

The present inventive concept relates to a light emitting device package and a method of manufacturing the same.

In general, light emitting device packages, light sources including light emitting devices such as light emitting diodes (LEDs), may be employed in various lighting devices, backlight units of display devices, vehicle headlamps, and the like. A light emitting device package may include a light emitting device for generating light, a package substrate supplying an electrical signal required for an operation of the light emitting device, and the like, and the light emitting device may be mounted on the package substrate by wire-bonding, flip-chip bonding or the like.

In order to increase the efficiency of the light emitting device package, a wide variety of light emitting device package structures are being developed.

### SUMMARY

An aspect of the present inventive concept may provide a light emitting device package allowing for a reduction in manufacturing cost while having superior reliability and light extraction efficiency, and a method of manufacturing the same.

According to an aspect of the present inventive concept, a light emitting device package may include: a light emitting device including a substrate and a light emitting structure including a first conductivity type semiconductor layer, an active layer, and a second conductivity type semiconductor layer, stacked on the substrate; a reflective conductive layer provided on the light emitting structure; and an electrode conductive layer provided on the reflective conductive layer and including a first electrode and a second electrode separated from each other in a first region, where the first electrode and the second electrode are electrically insulated from the reflective conductive layer and penetrate through the reflective conductive layer to be electrically connected to the first conductivity type semiconductor layer and the second conductivity type semiconductor layer, respectively, in a plurality of second and third regions different from the first region.

According to another aspect of the present inventive concept, a light emitting device package may include: a light emitting device including a substrate and a light emitting structure including a first conductivity type semiconductor layer, an active layer, and a second conductivity type semiconductor layer, stacked on the substrate; an electrode conductive layer including a first electrode electrically connected to the first conductivity type semiconductor layer and a second electrode electrically connected to the second conductivity type semiconductor layer and separated from the first electrode; and a reflective conductive layer disposed between the light emitting device and the electrode conductive layer, electrically separated from the light emitting device and the electrode conductive layer, and having an area greater than an area of the electrode conductive layer on the light emitting device.

According to another aspect of the present inventive concept, a method of manufacturing a light emitting device package may include: providing a light emitting device including a substrate and a light emitting structure including a first conductivity type semiconductor layer, an active layer, and a second conductivity type semiconductor layer, stacked on the substrate; forming a reflective conductive layer and an insulation layer surrounding the reflective conductive layer to partially expose a region of the light emitting device; forming an electrode conductive layer on the insulating layer; and forming a first electrode and a second electrode electrically separated from each other by removing the electrode conductive layer from a first region defined between the first electrode and the second electrode.

In one embodiment, a light emitting device package includes a light emitting device including a substrate and a light emitting structure including a first conductivity type semiconductor layer, an active layer, and a second conductivity type semiconductor layer, stacked on the substrate; a first insulating layer overlying the light emitting structure; a reflective conductive layer overlying the first insulating layer; a second insulating layer overlying the reflective conductive layer; first and second electrodes overlying the second insulating layer, the first and second electrodes spaced apart from each other and defining a first opening therebetween, where the first electrode is electrically connected to the first conductivity type semiconductor layer through a second opening defined through the reflective conductive layer and formed under the first electrode, and where the second electrode is electrically connected to the second conductivity type semiconductor layer through a third opening defined through the reflective conductive layer and formed under the second electrode.

In one embodiment, the reflective conductive layer extends below and between the first and second electrodes.

In one embodiment, the reflective conductive layer is electrically isolated from the first and second electrodes.

In one embodiment, the first and second insulating layer collectively form an insulation layer, the first electrode is electrically insulated from the reflective conductive layer at least by a portion of the insulation layer formed in the second opening and the second electrode is electrically insulated from the reflective conductive layer at least by a portion of the insulation layer formed in the third opening.

### BRIEF DESCRIPTION OF DRAWINGS

The above and other aspects, features and advantages of the present inventive concept will be more clearly understood from the following detailed description taken in conjunction with the accompanying drawings, in which:

FIG. 1A is a cross-sectional view illustrating a light emitting device package according to an exemplary embodiment of the present inventive concept;

FIG. 1B is a plan view of a light emitting device package according to the exemplary embodiment shown in FIG. 1A;

FIG. 1C is a plan view of a reflective conductive layer alone according to a light emitting device package shown in FIG. 1A;

FIG. 1D is a cross-sectional view illustrating a light emitting device package according to another embodiment;

FIG. 1E is a plan view of a reflective conductive layer alone according to the light emitting device package shown in FIG. 1D;

FIG. 2 through FIG. 8 are views illustrating a method of manufacturing the light emitting device package illustrated in FIG. 1;

FIG. 9 is a view illustrating a light emitting device package according to another exemplary embodiment of the present inventive concept;

FIG. 10 through FIG. 15 are views illustrating a method of manufacturing the light emitting device package illustrated in FIG. 9;

FIG. 16 is a view illustrating a light emitting device package according to another exemplary embodiment of the present inventive concept;

FIG. 17 is a view illustrating a wavelength conversion material applicable to the light emitting device package according to the exemplary embodiment of the present inventive concept;

FIG. 18 through FIG. 26 are views illustrating backlight units including the light emitting device package according to an exemplary embodiment of the present inventive concept;

FIG. 27 is a schematic, exploded perspective view of a display device including the light emitting device package according to an exemplary embodiment of the present inventive concept;

FIG. 28 through FIG. 31 are views illustrating lighting devices including the light emitting device package according to an exemplary embodiment of the present inventive concept; and

FIG. 32 through FIG. 34 are schematic views, each illustrating a network system according to an exemplary embodiment of the present inventive concept.

### DETAILED DESCRIPTION

Exemplary embodiments of the present inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

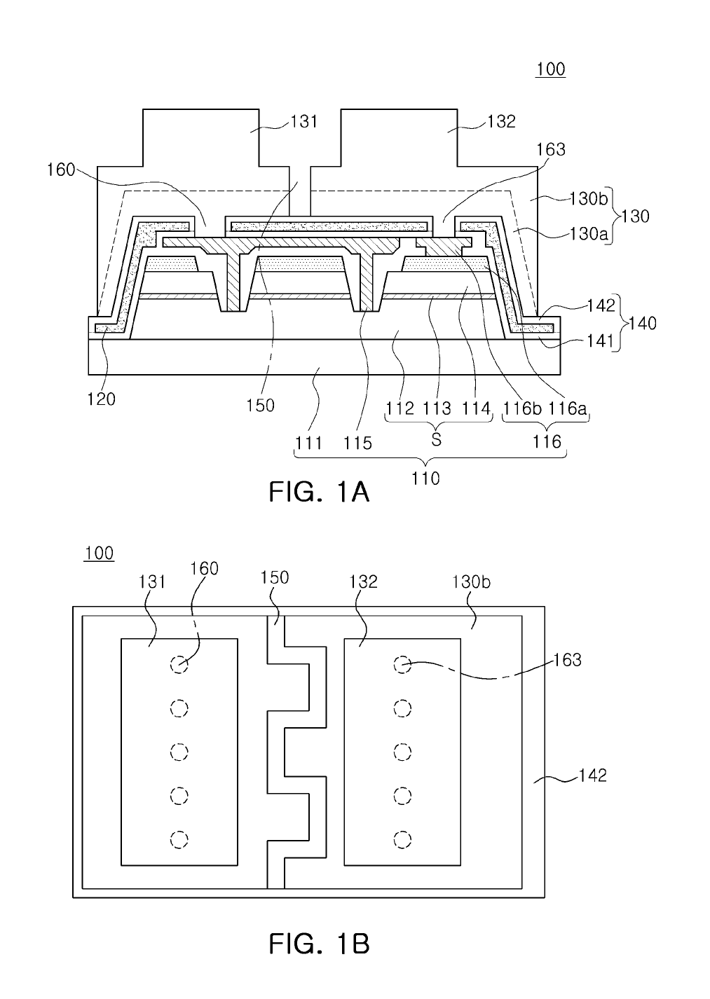

FIG. 1A is a cross-sectional view illustrating a light emitting device package according to an exemplary embodiment of the present inventive concept;

FIG. 1B is a plan view of a light emitting device package according to the exemplary embodiment shown in FIG. 1A.

Referring to FIG. 1A, a light emitting device package 100, according to an exemplary embodiment of the present inventive concept, may include a light emitting device 110 including a substrate 111, a light emitting structure S provided on the substrate 111, first and second contact electrodes 115 and 116 provided on the light emitting structure S, and a reflective conductive layer, e.g., a reflective metal layer 120 disposed on the light emitting device 110. The first and second contact electrodes 115 and 116 are formed using an electrode conductive layer such as an electrode metal layer 130. The light emitting structure S may include a first conductivity type semiconductor layer 112, an active layer 113, and a second conductivity type semiconductor layer 114, and the first and second contact electrodes 115 and 116 may be connected to the first and second conductivity type semiconductor layers 112 and 114, respectively.

The first conductivity type semiconductor layer 112 and the second conductivity type semiconductor layer 114 of the light emitting device 110 may be an n-type semiconductor layer and a p-type semiconductor layer, respectively. By way of example, the first conductivity-type semiconductor layer 112 and the second conductivity-type semiconductor layer 114 may be formed of a group III nitride semiconductor, such as a material having a composition of AlₓIn_{y}Ga_{1-x-y}N (0≦x≦1, 0≦y≦1, 0≦x+y≦1). The materials of the first conductivity-type semiconductor layer 112 and the second conductivity-type semiconductor layer 114 are not limited thereto, and may be an AlGaInP based semiconductor or an AlGaAs based semiconductor, for example.

On the other hand, the first and second conductivity-type semiconductor layers 112 and 114 may have a single layer structure or a multilayer structure in which respective layers having different compositions, thicknesses, or the like, are stacked on top of each other. For example, each of the first and second conductivity-type semiconductor layers 112 and 114 may include a carrier injection layer capable of improving injection efficiency of electrons and holes, and further, may have a superlattice structure formed in various manners.

The first conductivity-type semiconductor layer 112 may further include a current spreading layer (not illustrated) therein adjacent to the active layer 113. The current spreading layer may have a structure in which a plurality of AlₓIn_{y}Ga_{1-x-y}N layers having different compositions or different impurity contents are repeatedly stacked or may be partially formed of an insulating material layer.

The second conductivity-type semiconductor layer 114 may further include an electron-blocking layer (not illustrated) therein adjacent to the active layer 113. The electron blocking layer may have a structure in which a plurality of AlₓIn_{y}Ga_{1-x-y}N layers having different compositions are stacked or may have at least one layer configured of Al_{y}Ga_{(1-y)}N. The second conductivity-type semiconductor layer 114 may have a band gap greater than a band gap of the active layer 113 to prevent electrons from passing over the second conductivity-type semiconductor layer 114.

The light emitting device 110 may be formed using an MOCVD device. In order to manufacture the light emitting device 110, an organic metal compound gas (for example, trimethylgallium (TMG), trimethyl aluminum (TMA), or the like) and a nitrogen-containing gas (ammonia (NH₃) or the like) are supplied as a reaction gas to a reaction container in which a growth substrate is installed, and a temperature of the substrate is maintained at a high temperature of 900° C. to 1100° C., and thus gallium nitride compound semiconductors may be grown on the substrate while supplying an impurity gas thereto if necessary, to thereby allow the gallium nitride compound semiconductors to be stacked as an undoped layer, an n-type layer, and a p-type layer, on the substrate. An n-type impurity may be Si, widely known in the art and a p-type impurity may be Zn, Cd, Be, Mg, Ca, Ba, or the like. As the p-type impurity, Mg and Zn may be mainly used.

In addition, the active layer 113 interposed between the first and second conductivity-type semiconductor layers 12 and 14 may have a multiple quantum well (MQW) structure in which quantum well layers and quantum barrier layers are alternately stacked. In some embodiments, the active layer 113 may be formed of a nitride semiconductor including GaN and/or InGaN. Depending on exemplary embodiments, the active layer 113 may have a single quantum well (SQW) structure.

In some embodiments, as shown in FIG. 1A, the second contact electrode 116 may include a second lower contact electrode 116a and a second upper contact electrode 116b, although the shape of the second contact electrode 116 is not limited thereto. The first contact electrode 115 is illustrated as a single layer in the drawing. However, it may include a plurality of layers, similarly to the structure of the second contact electrode 116. The first contact electrode 115 may be separated from the active layer 113 and the second conductivity type semiconductor layer 114 by a first insulating layer 141 and may be electrically connected only to the first conductivity type semiconductor layer 112.

The first insulating layer 141, the reflective metal layer 120 and the second insulating layer 142 may be sequentially formed overlying the first and second contact electrodes 115 and 116. The second insulating layer 142 may be connected to the first insulating layer 141, and the first and second insulating layers 141, 142 may collectively form an insulation layer 140. The insulation layer 140 may substantially surround the portions of the reflective metal layer 120 in cross section. As a result, the reflective metal layer 120 may be electrically separated from the first and second contact electrodes 115 and 116 by the insulation layer 140. The electrode metal layer 130 may be provided on the insulation layer 140 overlying the reflective metal layer 120 and divided to form first and second electrodes 131 and 132. At least one of the first electrode 131 and the second electrode 132 is electrically isolated from the reflective metal layer 120. The electrode metal layer 130 may include a first layer 130a provided on the reflective metal layer 120 and a second layer 130b provided on the first layer 130a, and may be separated from the reflective metal layer 120 by the insulation layer 140. The second layer 130b may directly contact an upper surface of the first layer 130a and may be formed by an electroplating process using the first layer 130a as a seed layer, or the like. In some embodiments, the electrode metal layer 130 may be formed by depositing a single-layer conductive film.

Referring back to FIG. 1A, portions of the electrode metal layer 130 may be separated from each other to provide the first and second electrodes 131 and 132, which define a first region 150 therebetween. Therefore, the first region 150 may be a gap or opening separating the first and second electrodes 131 and 132 from each other. The first electrode 131 may pass through the insulation layer 140 to be electrically connected to the first contact electrode 115 through a second region 160 disposed in a lower portion of the first electrode 131, and, in a similar manner, the second electrode 132 may pass through the insulation layer 140 to be electrically connected to the second contact electrode 116 through a third region 163 disposed in a lower portion of the second electrode 132. That is, the first and second electrodes 131 and 132 may be connected to the first and second contact electrodes 115 and 116, respectively, in a corresponding one of the second and third regions 160, 163 disposed in positions different from that of the first region 150. The second and third regions 160, 163 may be openings or gaps defined through the reflective metal layer 120 and insulation layer 140.

When the first and second layers 130a and 130b of the electrode metal layer 130 are separated into multiple portions to form the first and second electrodes 131 and 132, a process of selectively removing the electrode metal layer 130 may be used. In general, the first and second electrodes 131 and 132 may be formed by forming the electrode metal layer 130 directly on the reflective metal layer 120 and removing all of the electrode metal layer 130 and the reflective metal layer 120 from the first region 150. According to some embodiments of the present disclosure, however, because a removal area of the reflective metal layer 120 is relatively large, light extraction efficiency of the light emitting device package 100 may be lowered.

In the exemplary embodiment of the present inventive concept, the insulation layer 140 may include the first insulating layer 141 disposed between the reflective metal layer 120 and the light emitting device 110 and the second insulating layer 142 disposed between the reflective metal layer 120 and the electrode metal layer 130. Further, as discussed above, the portions of the second insulating layer 142 may be connected to the first insulating layer 141 to collectively form the insulation layer 140 such that the reflective metal layer 120 may be electrically separated from the first and second contact electrodes 115 and 116 by the insulation layer 140. Thus, since the reflective metal layer 120 and the electrode metal layer 130 may be electrically separated or isolated from each other, it is unnecessary to remove the reflective metal layer 120 from the lower portion of the first region 150 as will be explained further below, comparing FIG. 1A and FIG. 1D. Consequently, since the reflective metal layer 120 is selectively removed in the second and third regions 160, 163 which together have an area that is relatively smaller than an area of the first region 150, when viewed from the top, light extraction efficiency of the light emitting device package 100 may be improved. In addition, in mounting the light emitting device package 100 on the package substrate, a resin containing no reflective material may be used as an underfill resin. Thus, manufacturing costs can be reduced. This will be explained further with respect to FIG. 1B, which is a plan view of a light emitting device package according to the exemplary embodiment shown in FIG. 1A.

Referring to FIG. 1B, the second and third regions 160, 163 may be openings, holes, or gaps defined through the reflective metal layer 120. The second and third regions 160, 163 may have shapes similar to those of a plurality of through holes. The first and second electrodes 131, 132 may be electrically connected to first and second contact electrodes 115 and 116, respectively, through the second and third regions 160, 163 with the insulation layer 140 disposed between the first and second electrodes 131, 132 and the reflective metal layer 120 in the second and third regions 160, 163. In this way, the reflective metal layer 120 may be electrically separated or isolated from the first and second contact electrodes 115 and 116 by the insulation layer 140.

Therefore, no reflective metal layer 120 needs to be removed in the first region 150 in contrast to a case where the reflective metal layer 120 is removed in the first region 150 together with the electrode metal layer 130 to form the first and second electrodes 131, 132 separated from each other (see FIG. 1D). This will be explained further with respect to FIGS. 1D and 1E.

In FIG. 1D, after a reflective conductive layer such as a reflective metal layer 120 is formed on an insulation layer 145 covering a light emitting structure S, an electrode metal layer 130 including a first layer 130a and a second layer 130b (similar to or same as the first layer 130a and the second layer 130b of FIG. 1A) is directly formed on the reflective metal layer 120. To separate first and second electrodes 131, 132 from each other, portions of both the electrode metal layer 130 and the reflective metal layer 120 in a first region 150 between the first and second electrodes 131, 132 are etched down to the insulation layer 145. Thus, a portion of the reflective metal layer 120 is removed in the first region 150, consequently lowering the overall light extraction efficiency. Also, an undercut problem occurs in a region designated by reference numeral 121 due to an etching process to remove the portion of the reflective conductive layer 120 in the first region 150.

In contrast, in the embodiment shown in FIG. 1A, the reflective metal layer 120 can still be present in the first region 150 between the first and second electrodes 131, 132, although the reflective metal layer 120 may not be present in the plurality of second and third regions 160, 163. The area of the first region 150 may be relatively larger than a total area of the plurality of second and third regions 160, 163 when viewed in plan view. As a result, an increased area of the reflective metal layer 120 may be secured to increase light extraction efficiency of the light emitting device package 100. In addition, because only the electrode metal layer 130 is removed and the reflective metal layer 120 is not removed in the first region 150, the occurrence of the undercut phenomenon due to excessive etching of the first layer 130a may be prevented, thereby preventing delamination of the electrode metal layer 130. Further, when the light emitting device package 100 is mounted on a package substrate, a resin material that does not include a reflective material as an underfill may not be needed, and the manufacturing costs can be reduced.

In this respect, FIG. 1C illustrates a plan view of the reflective metal layer 120 alone of the embodiment shown in FIG. 1A where the reflective conductive layer 120 is present under the first region 150 and FIG. 1E illustrates a plan view of the reflective conductive layer 120 alone according to another embodiment where the reflective conductive layer 120 is removed under the first region 150 as shown in FIG. 1D. Therefore, with the embodiment of FIG. 1A, an increase in the efficiency can be obtained compared to the other embodiment such as one shown in FIG. 1D.

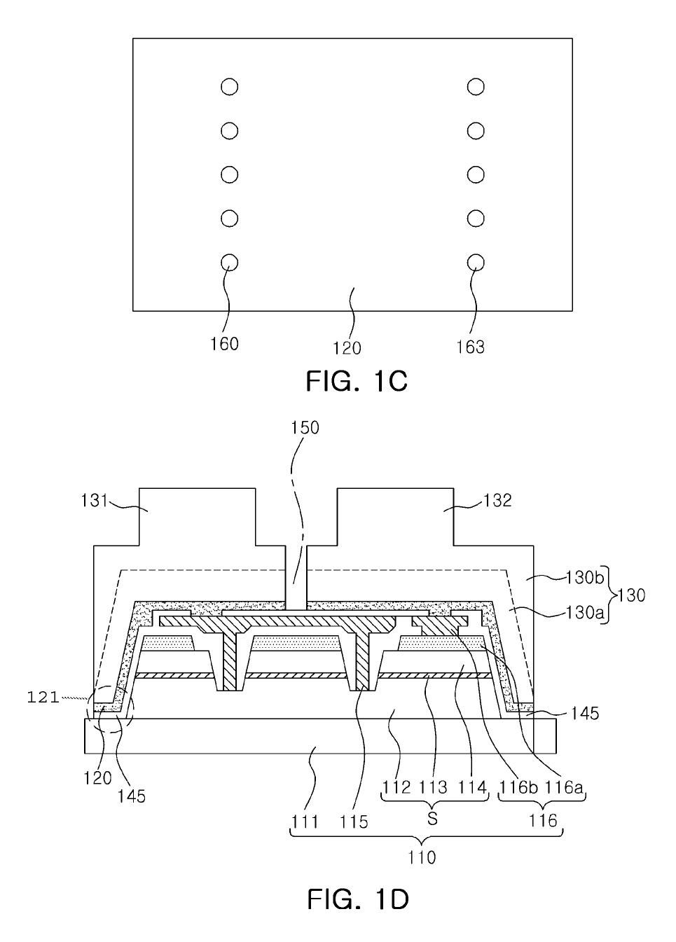

Hereinafter, a method of manufacturing the light emitting device package illustrated in FIG. 1A will be described with reference to FIG. 2 through FIG. 8.

Referring to FIG. 2, the light emitting structure S may be formed on the substrate 111. The light emitting structure S may include the first conductivity type semiconductor layer 112, the active layer 113, and the second conductivity type semiconductor layer 114. The substrate 111 may be a silicon (Si) substrate, but is not limited thereto. As described above, the first conductivity type semiconductor layer 112 and the second conductivity type semiconductor layer 114 may be an n-type semiconductor layer and a p-type semiconductor layer, respectively, and the active layer 113 may have a MQW or SQW structure.

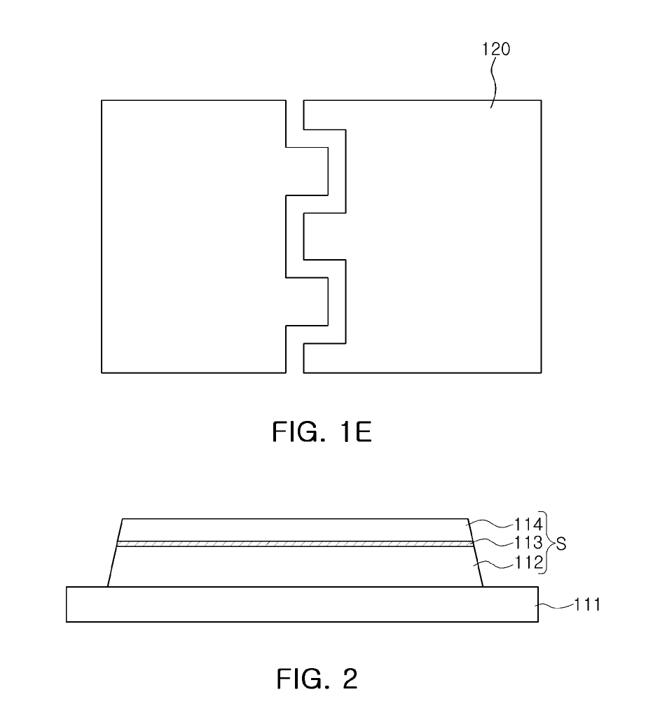

When the light emitting structure S is formed, as illustrated in FIG. 3, mesa etching may be performed to partially expose a region of the first conductivity type semiconductor layer 112, and on the mesa etched region, the first insulating layer 141, the first contact electrode 115, and the second contact electrode 116 may be formed. A portion of the first insulating layer 141 may be formed before the formation of the first and second contact electrodes 115 and 116, and the remaining portion of the first insulating layer 141 may be formed after the formation of the first and second contact electrodes 115 and 116. Thus, as illustrated in FIG. 3, the first insulating layer 141 may cover both upper and lower surfaces of the first and second contact electrodes 115 and 116. The first insulating layer 141 may contain polyethylene oxide (PEOX), and the first and second contact electrodes 115 and 116 may be reflective electrodes containing at least one among Ag, Al, Ni, Cr, Cu, Au, Pd, Pt, Sn, W, Rh, Ir, Ru, Mg, Zn and alloy materials containing these components.

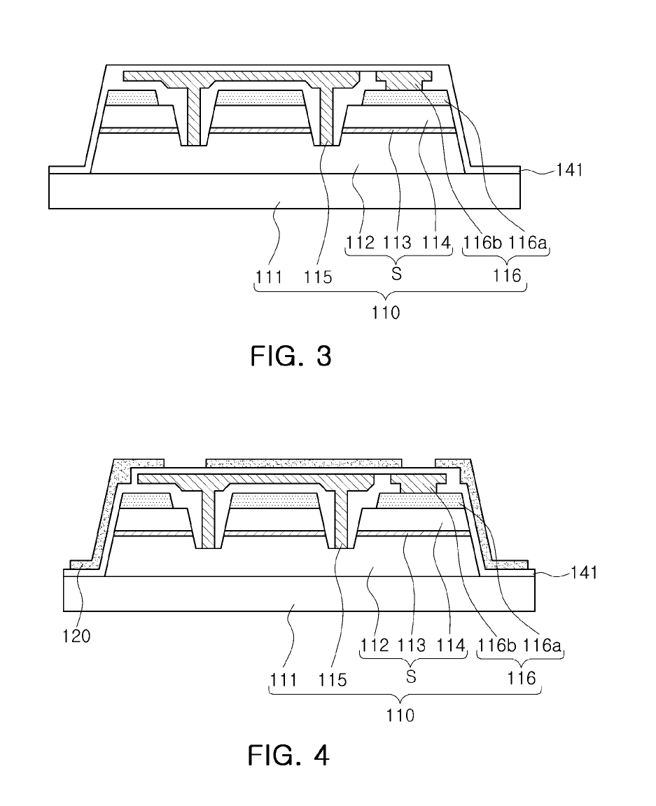

Then, referring to FIG. 4, the reflective metal layer 120 may be formed by using, for example, a lift-off process on partial regions of the first insulating layer 141. In order to selectively form the reflective metal layer 120, after forming a mask layer covering the partial regions of the first insulating layer 141, at least one chosen from Ag, Al, Ni, Cr, Cu, Au, Pd, Pt, Sn, W, Rh, Ir, Ru, Mg, Zn or alloy materials containing these components may be deposited thereon to form the reflective metal layer 120 using a electroplating process.

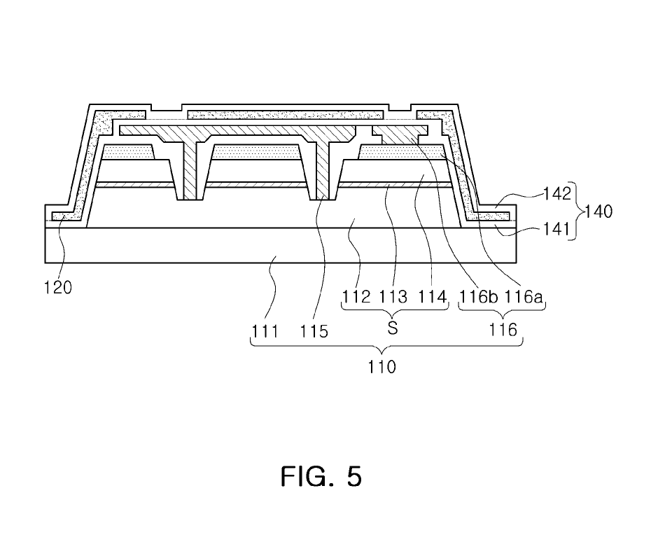

When the reflective metal layer 120 is formed, as illustrated in FIG. 5, the second insulating layer 142 may be formed on the reflective metal layer 120. The second insulating layer 142 may contain polyethylene oxide (PEOX), similar to the first insulating layer 141. In order to enhance adhesion between the second insulating layer 142 and the reflective metal layer 120 as well as to prevent delamination, a bonding metal layer may be further formed on the reflective metal layer 120, before the second insulating layer 142 is formed.

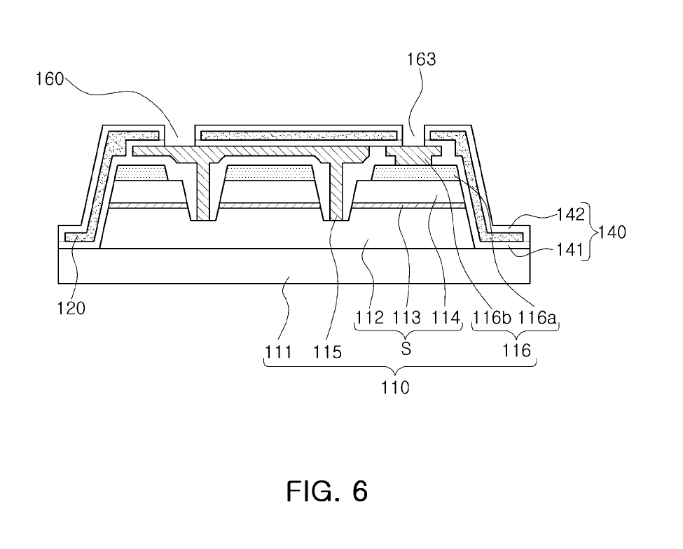

Then, referring to FIG. 6, the first and second insulating layers 141 and 142 may be removed to form openings 160, 163 to partially expose the first and second contact electrodes 115 and 116. A mask layer exposing only the plurality of the openings 160, 163 may be formed in the second insulating layer 142, and an etching process may be conducted to thereby partially expose regions of the first and second contact electrodes 115 and 116. The plurality of the openings 160, 163 may have shapes similar to those of a plurality of through holes.

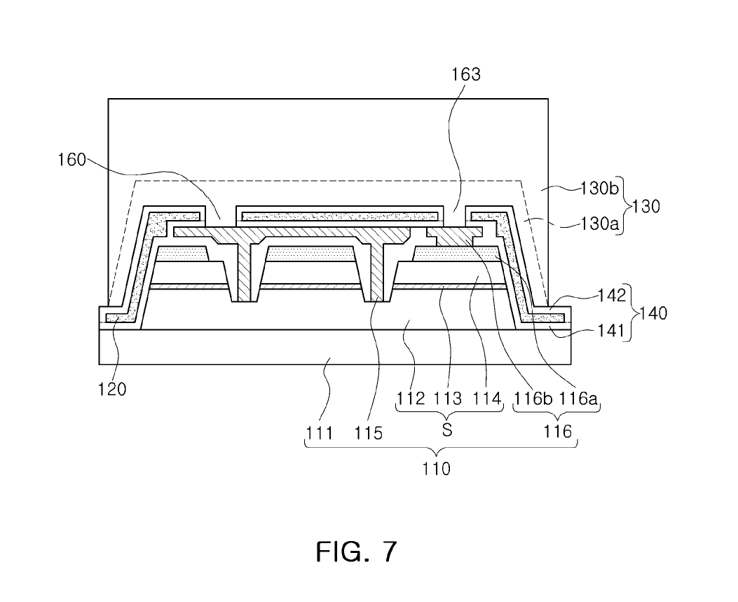

When the regions of the first and second contact electrodes 115 and 116 are partially exposed through the plurality of openings 160, 163, the electrode metal layer 130 may be formed as illustrated in FIG. 7. The electrode metal layer 130 may include the first layer 130a and the second layer 130b, and the first layer 130a may be provided as a seed layer for forming the second layer 130b through an electroplating process and may be formed by a sputtering process or the like. The first layer 130a may contain Ti and/or Cu. In some exemplary embodiments, prior to the formation of the first layer 130a, a bonding metal layer may be formed on the second insulating layer 142 in order to prevent delamination of the electrode metal layer 130.

On the other hand, the second layer 130b may be formed by an electroplating process using the first layer 130a as a seed layer. As illustrated in FIG. 7, the second layer 130b may have a thickness relatively greater than a thickness of the first layer 130a. In an exemplary embodiment, if the first layer 130a has a thickness of about 20 μm, the second layer 130b may have a thickness of about 100 μm.

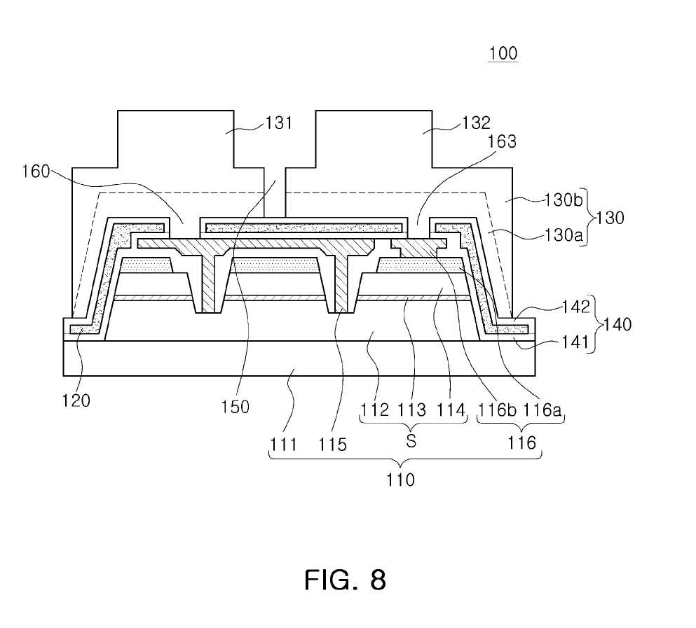

Then, referring to FIG. 8, the first and second electrodes 131 and 132 may be formed by selectively etching the electrode metal layer 130. The first and second electrodes 131 and 132 may include first and second metal posts 131a and 132a formed by selectively etching the second layer 130b of the electrode metal layer 130. After forming the first and second metal posts 131a and 132a, the first layer 130a and the second layer 130b of the electrode metal layer 130 may be removed, thereby forming the first region (or first opening) 150 to partially expose the insulation layer 140. Consequently, the first and second electrodes 131 and 132 may be formed. That is, the electrode metal layer 130 may be removed in the first region 150, and thus the first and second electrodes 131 and 132 may be electrically separated from each other.

In the case of manufacturing the light emitting device package 100 according to the manufacturing method described with reference to FIG. 2 through FIG. 8, the removal process of the reflective metal layer 120 may be omitted. Thus, in comparison with an existing method of forming the electrode metal layer 130 directly on the reflective metal layer 120 and simultaneously removing the electrode metal layer 130 and the reflective metal layer 120 from the first region 150, since the reflective metal layer 120 remains on the lower portion of the first region 150, a relatively large area of the reflective metal layer 120 may be secured. That is, in the exemplary embodiment of the present inventive concept, an area of the reflective metal layer 120 may be greater than an area of the electrode metal layer 130, when viewed in plan view. In addition, in the existing method of simultaneously removing the electrode metal layer 130 and the reflective metal layer 120, an area of the first layer 130a may be reduced due to an undercut phenomenon occurring in the first region 150 to increase the possibility of delamination in the electrode metal layer 130. In the exemplary embodiment of the present inventive concept, only the electrode metal layer 130 is removed in the first region 150, and thus the occurrence of the undercut phenomenon due to excessive etching may be solved.

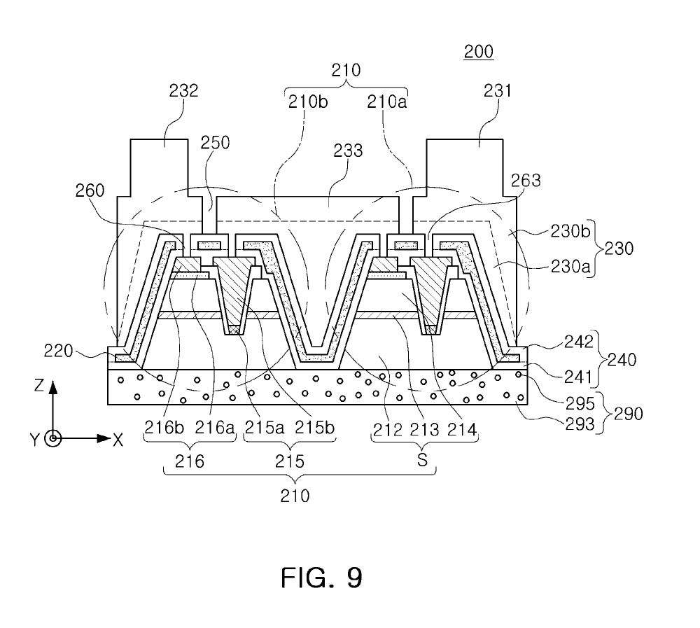

FIG. 9 is a cross-sectional view illustrating a light emitting device package according to another exemplary embodiment of the present inventive concept.

Referring to FIG. 9, a light emitting device package 200 according to another exemplary embodiment of the present inventive concept may include a light emitting device 210 having a light emitting structure S and first and second contact electrodes 215 and 216 provided on the light emitting structure S, a reflective conductive layer such as a reflective metal layer 220 and an electrode metal layer 230 disposed on the light emitting device 210, and an encapsulating part 290.

The structure of the light emitting device 210 may be similar to that of the light emitting device 110 included in the light emitting device package 100 illustrated in FIG. 1A. The light emitting structure S may include a first conductivity type semiconductor layer 212, an active layer 213, and a second conductivity type semiconductor layer 214, and may be formed in a manner in which the light emitting structure S is formed on a predetermined growth substrate, and then the growth substrate is removed therefrom. The encapsulating part 290 may be attached to one surface of the first conductivity type semiconductor layer 212 from which the growth substrate has been removed. The encapsulating part 290 may contain a resin 293 having excellent light transmittance and a wavelength conversion material 295 converting a wavelength of light emitted by the light emitting device 210 into another wavelength of light.

The first conductivity type semiconductor layer 212 and the second conductivity type semiconductor layer 214 may be an n-type semiconductor layer and a p-type semiconductor layer, respectively, and the active layer 213 may emit light by the recombination of electrons and holes transferred from the first conductivity type semiconductor layer 212 and the second conductivity type semiconductor layer 214. The active layer 213 may have a MQW or SQW structure. Each of the first and second contact electrodes 215 and 216 may include lower contact electrodes 215a and 216a and upper contact electrodes 215b and 216b.

The light emitting device package 200 according to the exemplary embodiment illustrated in FIG. 9 may include two light emitting devices 210a and 210b connected to each other in series. The second conductivity type semiconductor layer 214 of the first light emitting device 210a and the first conductivity type semiconductor layer 212 of the second light emitting device 210b may be connected to each other by a connection electrode 233, and accordingly, the light emitting device package 200 may include the first and second light emitting devices 210a and 210b connected to each other in series.

The reflective metal layer 220 and the electrode metal layer 230 may be formed on the light emitting device 210. A first insulating layer 241 may be disposed between the reflective metal layer 220, and the light emitting device 210 and a second insulating layer 242 may be disposed between the reflective metal layer 220 and the electrode metal layer 230. Thus, the reflective metal layer 220 may be electrically separated from the light emitting device 210 and the electrode metal layer 230. The reflective metal layer 220 may contain at least one of Ag, Al, Ni, Cr, Cu, Au, Pd, Pt, Sn, W, Rh, Ir, Ru, Mg, Zn or alloy materials containing these components.

The electrode metal layer 230 may include a first layer 230a and a second layer 230b, and the first layer 230a may be formed by a sputtering process or the like. The first layer 230a may contain Ti and/or Cu. The second layer 230b may be formed by an electroplating process using the first layer 230a as a seed layer. The second layer 230b may have a thickness relatively greater than a thickness of the first layer 230a. As illustrated in FIG. 9, portions of the second layer 230b may be provided as first and second metal posts 231 and 232.

The electrode metal layer 230 may be selectively removed to form first and second electrodes 231 and 232 and the connection electrode 233, thereby defining first regions 250 therebetween. Therefore, the first regions 250 may be a gap or opening separating the first and second electrodes 231 and 232 and the connection electrode 233. The connection electrode 233 may connect the first and second light emitting devices 210a and 210b of the light emitting device package 200 to each other in series. The first electrode 231 may be electrically connected to the first conductivity type semiconductor layer 212 of the first light emitting device 210a and the second electrode 232 may be electrically connected to the second conductivity type semiconductor layer 214 of the second light emitting device 210b. Thus, when an electrical signal is input to the first and second electrodes 231 and 232, the first and second light emitting devices 210a and 210b may simultaneously operate to emit light. In order to electrically separate the first and second electrodes 231 and 232 and the connection electrode 233 from each other, the light emitting device package 200 may include the plurality of first regions 250. As discussed above, portions of the electrode metal layer 230 may be partially removed in the plurality of first regions 250 to form the first and second electrodes 231 and 232 and the connection electrode 233. At least two of the first electrode 231, the second electrode 232, and the connection electrode 233 are electrically isolated from the reflective metal layer 220.

In some embodiments, the reflective metal layer 220 may not be present in a plurality of second and third regions 260 and 263, respectively, which are different from the plurality of first regions 250. That is, the first and second electrodes 231 and 232 and the connection electrode 233 may penetrate through the reflective metal layer 220 to be connected to the first and second contact electrodes 215 and 216, respectively, in a corresponding one of the plurality of second and third regions 260, 263. Referring to the first light emitting device 210a, the reflective metal layer 220 and an insulation layer 240 may not be present in the plurality of second and third regions 260, 263, and the first electrode 231 may be electrically connected to the first contact electrode 215 and the connection electrode 233 may be electrically connected to the second contact electrode 216. In the case of the second light emitting device 210b, the connection electrode 233 may be electrically connected to the first contact electrode 215, and the second electrode 232 may be electrically connected to the second contact electrode 216, in the plurality of second regions 260.

An area of the plurality of first regions 250 may be relatively larger than a total area of the plurality of second and third regions 260, 263 when viewed in plan view. In some embodiments, the reflective metal layer 220 may not be present in the plurality of second and third regions 260, 263, and an increased area of the reflective metal layer 220 may be secured to increase light extraction efficiency of the light emitting device package 200. In addition, when the first regions 250 are formed, since only the electrode metal layer 230 is removed and the reflective metal layer 220 is not removed, the occurrence of the undercut phenomenon due to excessive etching of the first layer 230a may be prevented, thereby preventing delamination of the electrode metal layer 230.

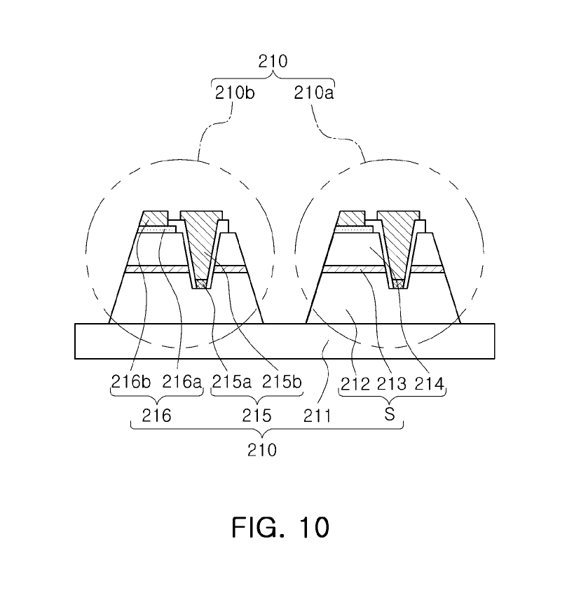

Hereinafter, a method of manufacturing the light emitting device package illustrated in FIG. 9 will be described with reference to FIG. 10 through FIG. 15.

Referring to FIG. 10, the plurality of light emitting devices 210a and 210b may be prepared. Each of the light emitting devices 210a and 210b may include a light emitting structure S including the first conductivity type semiconductor layer 212, the active layer 213, and the second conductivity type semiconductor layer 214 provided a substrate 211, and the first and second contact electrodes 215 and 216. The substrate 211 may be a silicon (Si) substrate, and the first conductivity type semiconductor layer 212 and the second conductivity type semiconductor layer 214 may be an n-type semiconductor layer and a p-type semiconductor layer, respectively. The active layer 213 may emit light due to the recombination of electrons and holes and have a MQW or SQW structure.

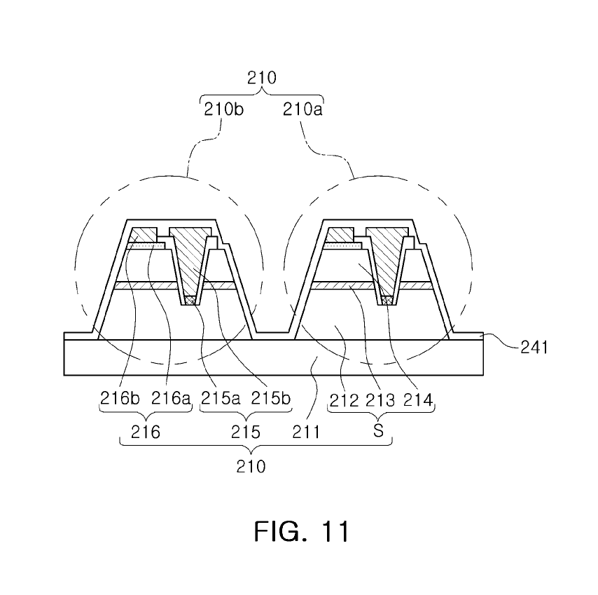

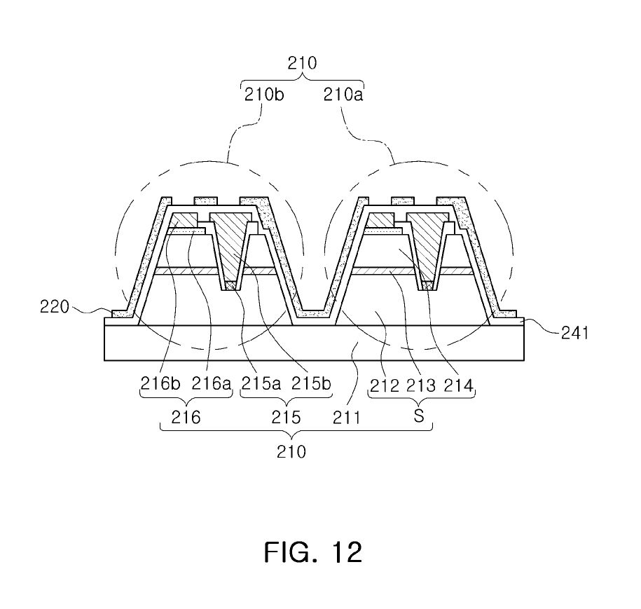

Referring to FIG. 11, the first insulating layer 241 may be prepared on the light emitting devices 210a and 210b. The first insulating layer 241 may contain an insulating material such as polyethylene oxide (PEOX) or the like, and may be continuously disposed on the light emitting devices 210a and 210b. Then, referring to FIG. 12, the reflective metal layer 220 may be selectively formed on partial regions of the first insulating layer 241.

The reflective metal layer 220 may contain a material capable of reflecting light emitted from the active layer 213, such as at least one chosen from Ag, Al, Ni, Cr, Cu, Au, Pd, Pt, Sn, W, Rh, Ir, Ru, Mg, Zn or alloy materials containing these components. In order to selectively form the reflective metal layer 220 on the partial regions of the first insulating layer 241, a mask layer may be formed on the first insulating layer 241, and the reflective metal layer 220 may be formed in only a region in which the mask layer is not formed. In this case, the region of the first insulating layer 241 covered by the mask layer may include a plurality of regions separated from each other.

Alternatively, a reflective metal layer 220 is formed by blanket depositing a conductive layer on the first insulating layer 241 and removing portions of the conductive layer using an etch mask to form the reflective metal layer 220.

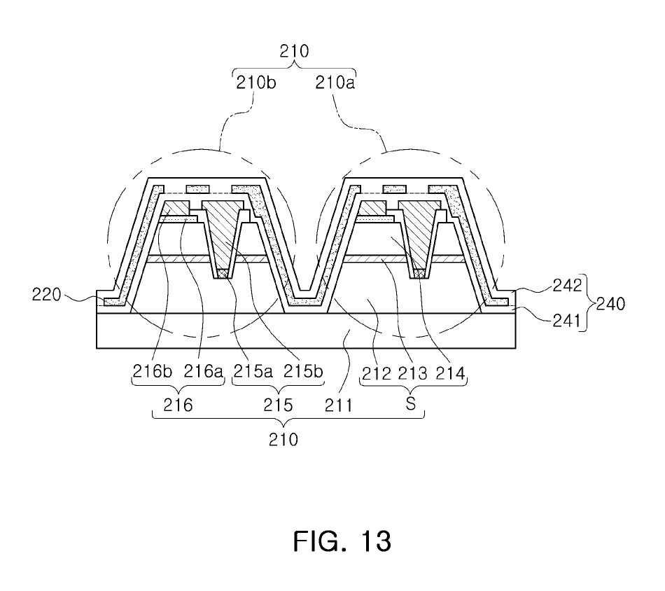

Referring to FIG. 13, the second insulating layer 242 may be formed on the first insulating layer 241 and the reflective metal layer 220. The second insulating layer 242 may be continuously formed on substantially the entire surface of the reflective metal layer 220 and the first insulating layer 241, and thus, the second insulating layer 242 may be connected to the first insulating layer 241, and the first and second insulating layers 241, 242 may collectively form an insulation layer 240, as illustrated in FIG. 13. Upper and lower surfaces and side surfaces of the reflective metal layer 220 may be substantially surrounded by the first and second insulating layers 241 and 242.

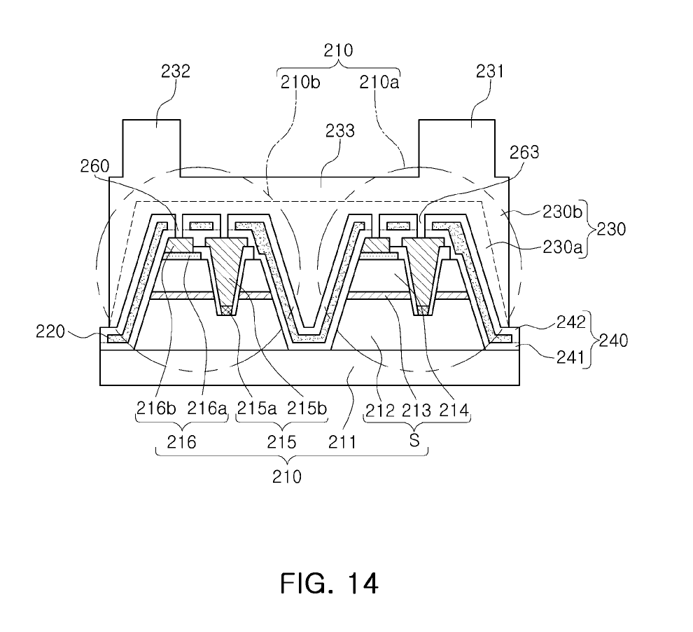

Referring to FIG. 14, the electrode metal layer 230 may be formed on the second insulating layer 242. The electrode metal layer 230 may include the first layer 230a and the second layer 230b, and the first layer 230a may be formed by a sputtering process or a deposition process and may contain Ti and/or Cu. The second layer 230b may be formed by an electroplating process using the first layer 230a as a seed layer. The second layer 230b may have a thickness relatively greater than a thickness of the first layer 230a. In an exemplary embodiment, if the first layer 230a has a thickness of about 20 μm, the second layer 230b may have a thickness of about 100 μm. The second layer 230b may include a metal post for connecting the light emitting device package 200 to a circuit board and the like.

Also, prior to the formation of the electrode metal layer 230, a region of the insulation layer 240 may be partially removed in the plurality of second and third regions 260, 263 to expose the first and second contact electrodes 215 and 216, respectively. Referring to FIG. 14, the insulation layer 240 may be removed in portions of an upper surface of each of the first and second light emitting devices 210a and 210b to expose the first and second contact electrodes 215 and 216. The portions to which the first and second contact electrodes 215 and 216 are exposed may be defined as the plurality of second and third regions 260, 263. The plurality of second and third regions 260, 263 may be substantially identical to regions in which the reflective metal layer 220 is not formed. Thus, only the insulation layer 240, rather than the reflective metal layer 220, may be removed in the plurality of second and third regions 260, 263 to thereby expose the first and second contact electrodes 215 and 216, respectively. In the plurality of second and third regions 260, 263, the electrode metal layer 230 may be electrically connected to the first and second contact electrodes 215 and 216 and may be electrically separated from the reflective metal layer 220.

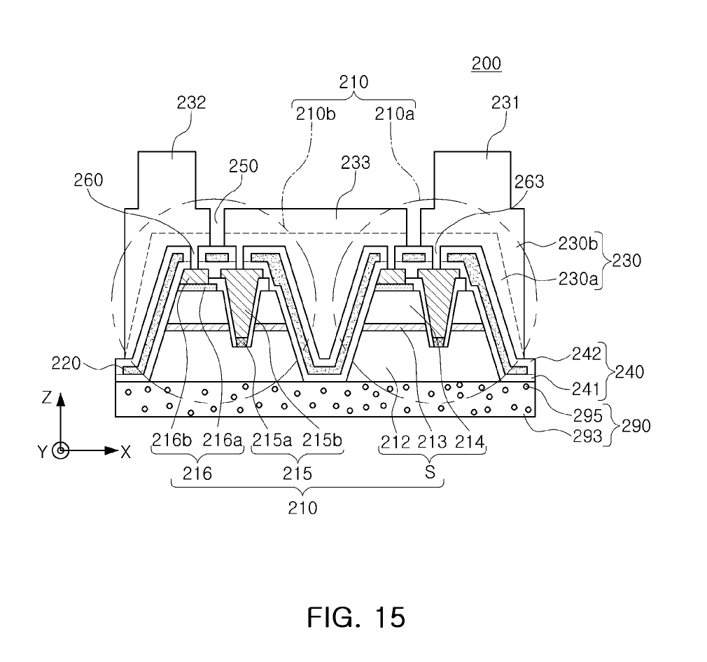

Then, referring to FIG. 15, the electrode metal layer 230 may be removed in the first regions 250 to form the first and second electrodes 231 and 232 and the connection electrode 233. The connection electrode 233 may electrically connect the second contact electrode 216 of the first light emitting device 210a to the first contact electrode 215 of the second light emitting device 210b. Thus, the first light emitting device 210a and the second light emitting device 210b may be connected to each other in series.

On the other hand, after forming the first and second electrodes 231 and 232 and the connection electrode 233, the substrate 211 may be removed through a process such as a laser lift-off (LLO) process or the like, and the encapsulating part 290 may be attached to the light emitting structure S. The encapsulating part 290 may contain the wavelength conversion material 295 such as phosphors, quantum dots, or the like, together with an epoxy resin 293 capable of protecting the light emitting devices 210a and 210b.

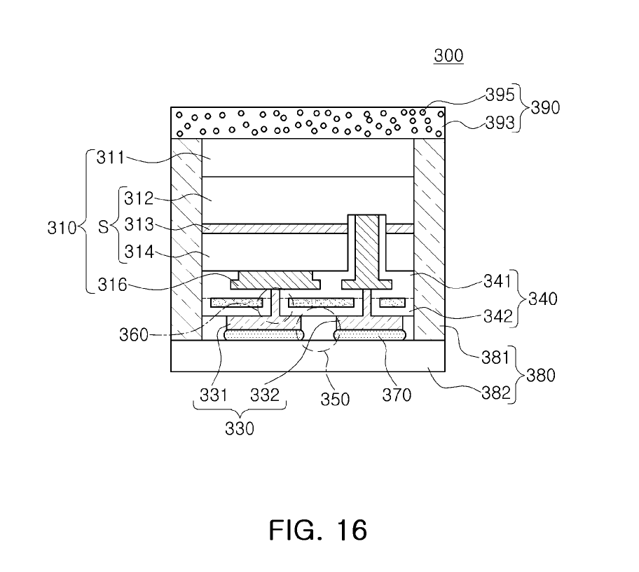

FIG. 16 is a view illustrating a light emitting device package according to another exemplary embodiment of the present inventive concept.

Referring to FIG. 16, a light emitting device package 300 according to another exemplary embodiment of the present inventive concept may include a light emitting device 310, a package body 380 including a reflective wall 381 and a package substrate 382, and an encapsulating part 390. The light emitting device 310 may include a substrate 311, a light emitting structure S formed on the substrate 311, first and second contact electrodes 315 and 316 respectively connected to first and second conductivity type semiconductor layers 312 and 314 included in the light emitting structure S, and the like. Configurations of the first and second conductivity type semiconductor layers 312 and 314 and an active layer 313 included in the light emitting structure S may be similar to those described with reference to FIG. 1A through FIG. 9. Meanwhile, the substrate 311 may be a support substrate containing a material having excellent light transmitting properties.

The light emitting device 310 may be flip-chip bonded to the package substrate 382 by first and second electrodes 331 and 332 and a solder bump 370. Each of the first and second electrodes 331 and 332 may penetrate through an insulating layer 340 to be connected to the first and second contact electrodes 315 and 316. The insulating layer 340 may include a first insulating layer 341 and a second insulating layer 342, and a reflective metal layer 320 may be disposed between the first and second insulating layers 341 and 342. The reflective metal layer 320 may be selectively formed in the remaining region except for a plurality of second and third regions 360, 363 in which the first and second electrodes 331 and 332 may penetrate through the insulating layer 340 to be connected to the first and second contact electrodes 315 and 316, respectively. The reflective metal layer 320 may contain a highly-reflective metal material and may reflect light emitted from the active layer 313 to improve light extraction efficiency of the light emitting device package 300.

The first and second electrodes 331 and 332 may be electrically separated or isolated from each other in a first region 350. The first region 350 may be a region different from the plurality of second and third regions 360, 363 in which the reflective metal layer 320 is not formed. If the first and second electrodes 331 and 332 contain a highly-reflective metal material, similar to the case of the reflective metal layer 320, a highly-reflective metal layer may be practically disposed on the entire surface of a lower portion of the light emitting device 310, and thus light extraction efficiency of the light emitting device package 300 may be increased.

As illustrated in FIG. 16, the reflective wall 381 may be attached to a side surface of the light emitting device 310 or may be separated from the side surface of the light emitting device 310 by a predetermined interval. The reflective wall 381 may contain a highly-reflective metal layer, such as TiO₂. An upper surface of the reflective wall 381 may be coplanar with an upper surface of the substrate 311 and the encapsulating part 390 may be disposed on the upper surfaces of the reflective wall 381 and the substrate 311. The encapsulating part 390 may contain a transparent resin 393 having excellent light transmittance and a wavelength conversion material 395 such as phosphors, quantum dots, or the like.

Various materials such as phosphors and/or quantum dots may be used as the wavelength conversion material, a material for converting a wavelength of light emitted from the light emitting device.

In an exemplary embodiment, the phosphors applied to the wavelength conversion material may have the following empirical formulas and colors:

Oxides: Yellow and green Y₃Al₅O₁₂:Ce, Tb₃Al₅O₁₂:Ce, Lu₃Al₅O₁₂:Ce

Silicates: Yellow and green (Ba,Sr)₂SiO₄:Eu, yellow and orange (Ba,Sr)₃SiO₅:Ce

Nitrides: Green β-SiAlON:Eu, yellow La₃Si₆N₁₁:Ce, orange α-SiAlON:Eu, red CaAlSiN₃:Eu, Sr₂Si₅N₈:Eu, SrSiAl₄N₇:Eu, SrLiAl₃N₄: Eu, Ln₄₋ₓ(Eu_{z}M_{1-z})ₓSi_{12-y}Al_{y}O_{3+x+y}N_{18-x-y}(0.5≦x≦3, 0<z<0.3, 0<y≦4) Equation (1)

In Equation (1), Ln may be at least one type of element selected from the group consisting of Group IIIa elements and rare earth elements, and M may be at least one type of element selected from the group consisting of calcium (Ca), barium (Ba), strontium (Sr), and magnesium (Mg).

Fluorides: KSF-based red K₂SiF₆:Mn₄⁺, K₂TiF₆:Mn₄⁺, NaYF₄:Mn₄⁺, NaGdF₄:Mn₄⁺ (For example, a composition ratio of Mn may be 0<z<=0.17).

Phosphor compositions should basically conform to stoichiometry, and respective elements may be substituted with other elements of respective groups of the periodic table. For example, strontium (Sr) may be substituted with barium (Ba), calcium (Ca), magnesium (Mg), and the like within the alkaline earth group (II), and yttrium (Y) may be substituted with lanthanum (La) based elements such as terbium (Tb), lutetium (Lu), scandium (Sc), gadolinium (Gd), and the like. Also, europium (Eu), an activator, may be substituted with cerium (Ce), terbium (Tb), praseodymium (Pr), erbium (Er), ytterbium (Yb), and the like, according to a desired energy level, and an activator may be applied alone or with a co-activator for modifying characteristics of phosphors.

In particular, in order to enhance reliability at high temperatures and high humidity, a fluoride-based red phosphor may be coated with a fluoride not containing manganese (Mn) or with organic materials thereon. The organic materials may be coated on the fluoride-based red phosphor coated with a fluoride not containing manganese (Mn). Unlike other phosphors, the fluoride-based red phosphor may realize a narrow full width at half maximum (FWHM) equal to or less than 40 nm, and thus, it may be utilized in high resolution TVs such as UHD TVs.

Table 1 below illustrates types of phosphors in application fields of light emitting device packages using a blue LED chip having a wavelength of 440 nm to 460 nm or a UV LED chip having a wavelength of 380 nm to 440 nm.

TABLE 1

| USE | Phosphor | USE | Phosphor |
|---|---|---|---|
| LED TV BLU | β-SiAlON:Eu2+ | Side View | Lu₃Al₅O₁₂:Ce3+ |
| | (Ca,Sr)AlSiN₃:Eu2+ | (Mobile, Note PC) | Ca-α-SiAlON:Eu2+ |
| | La₃Si₄N₁₁:Ce3+ | | La₃Si₆N₁₁:Ce3+ |
| | K₂SiF₆:Mn4+ | | (Ca,Sr)AlSiN₃:Eu2+ |
| | SrLiAl3N4:Eu | | Y₃Al₅O₁₂:Ce3+ |
| | Ln₄₋ₓ(Eu_{z}M_{1-z})ₓSi_{12-y}Al_{y}O_{3+x+y}N_{18-x-y} | | (Sr,Ba,Ca,Mg)2SiO4:Eu2+ |
| | (0.5 ≦ x ≦ 3, 0 < z < 0.3, 0 < y ≦ 4) | | K₂SiF₆:Mn4+ |
| | K2TiF6:Mn4+ | | SrLiAl3N4:Eu |
| | NaYF4:Mn4+ | | Ln₄₋ₓ(Eu_{z}M_{1-z})ₓSi_{12-y}Al_{y}O_{3+x+y}N_{18-x-y} |
| | NaGdF4:Mn4+ | | (0.5 ≦ x ≦ 3, 0 < z < 0.3, 0 < y ≦ 4) |
| | | | K2TiF6:Mn4+ |
| | | | NaYF4:Mn4+ |
| | | | NaGdF4:Mn4+ |
| Lighting | Lu₃Al₅O₁₂:Ce3+ | Electronic | Lu₃Al₅O₁₂:Ce3+ |
| device | Ca-α-SiAlON:Eu2+ | device | Ca-α-SiAlON:Eu2+ |
| | La₃Si₆N₁₁:Ce3+ | (Head Lamp, etc.) | La₃Si₆N₁₁:Ce3+ |
| | (Ca,Sr)AlSiN₃:Eu2+ | | (Ca,Sr)AlSiN₃:Eu2+ |
| | Y₃Al₅O₁₂:Ce3+ | | Y₃Al₅O₁₂:Ce3+ |
| | K₂SiF₆:Mn4+ | | K₂SiF₆:Mn4+ |
| | SrLiAl3N4:Eu | | SrLiAl3N4:Eu |
| | Ln₄₋ₓ(Eu_{z}M_{1-z})ₓSi_{12-y}Al_{y}O_{3+x+y}N_{18-x-y} | | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4) | | (0.5 ≦ x ≦ 3, 0 < z < 0.3, 0 < y ≦ 4) |
| | K2TiF6:Mn4+ | | K2TiF6:Mn4+ |
| | NaYF4:Mn4+ | | NaYF4:Mn4+ |
| | NaGdF4:Mn4+ | | NaGdF4:Mn4+ |

Meanwhile, the wavelength conversion material may include quantum dots (QD) provided to be used in place of phosphors or to be mixed with phosphors.

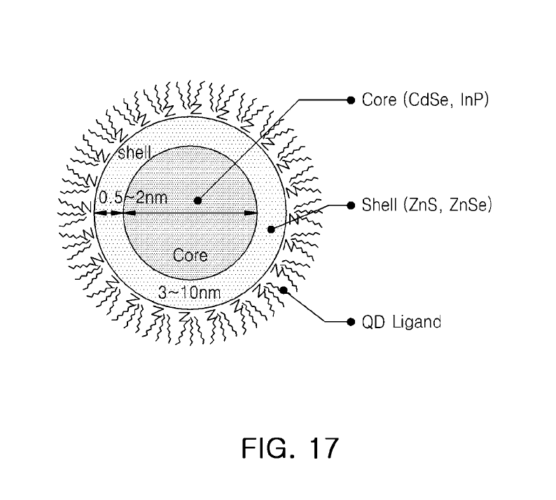

FIG. 17 is a view illustrating a cross-sectional structure of a quantum dot. The quantum dot may have a core-shell structure including Group II-VI or Group III-V compound semiconductors. For example, the quantum dot may have a core such as CdSe or InP or a shell such as ZnS or ZnSe. Also, the quantum dot may include a ligand to stabilize the core and shell. For example, the core may have a diameter ranging from 1 nm to 30 nm, and preferably, 3 nm to 10 nm in an exemplary embodiment. The shell may have a thickness ranging from 0.1 nm to 20 nm, and preferably, 0.5 nm to 2 nm in an exemplary embodiment.

The quantum dots may be used to realize various colors according to sizes and, in particular, when the quantum dot is used as a phosphor substitute, it may be used as a red or green phosphor. The use of a quantum dot may realize a narrow FWHM (e.g., about 35 nm).

The wavelength conversion material may be contained in an encapsulator, or alternatively, the wavelength conversion material may be manufactured as a film in advance and attached to a surface of an optical device such as an LED chip or a light guide plate. When the wavelength conversion material is manufactured as a film in advance, a wavelength conversion material having a uniform thickness may be easily implemented.

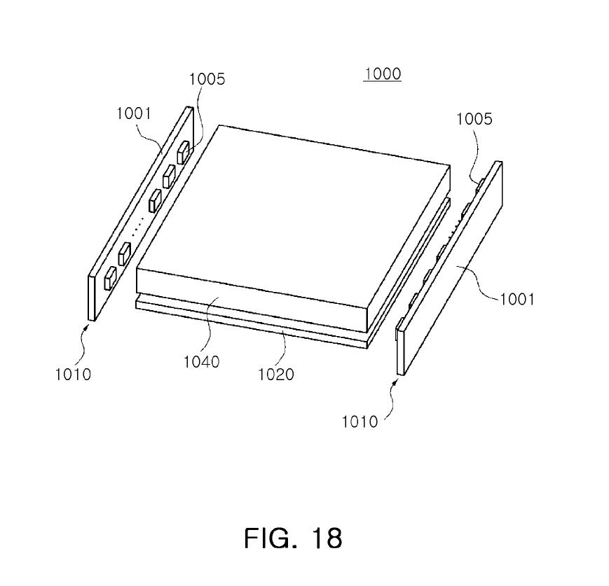

FIG. 18 through FIG. 26 are views illustrating backlight units including the light emitting device package according to an exemplary embodiment of the present inventive concept.

Referring to FIG. 18, a backlight unit 1000 may include a light guide plate 1040 and light source modules 1010 provided on both sides of the light guide plate 1040. Also, the backlight unit 1000 may further include a reflective plate 1020 disposed below the light guide plate 1040. The backlight unit 1000 according to the exemplary embodiment may be an edge type backlight unit.

According to an exemplary embodiment, the light source module 1010 may be provided only on one side of the light guide plate 1040 or may further be provided on the other side thereof. The light source module 1010 may include a printed circuit board (PCB) 1001 and a plurality of light sources 1005 mounted on an upper surface of the PCB 1001. The light emitting device packages 100, 200, and 300 described with reference to FIG. 1A, FIG. 9, FIG. 16 and the like may be applied to the plurality of light sources 1005.

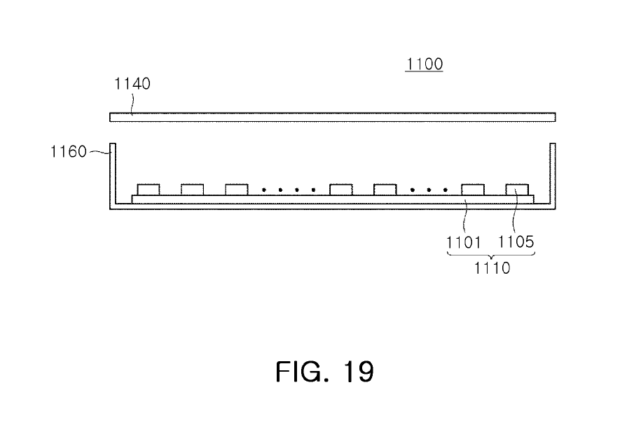

FIG. 19 is a view illustrating an embodiment of a direct type backlight unit.

Referring to FIG. 19, a backlight unit 1100 may include alight diffuser plate 1140 and a light source module 1110 arranged below the light diffuser plate 1140. Also, the backlight unit 1100 may further include a bottom case 1160 disposed below the light diffuser plate 1140 and accommodating the light source module 1110. The backlight unit 1100 according to the exemplary embodiment may be a direct type backlight unit. [0180] The light source module 1110 may include a printed circuit board (PCB) 1101 and a plurality of light sources 1105 mounted on an upper surface of the PCB 1101. The light emitting device packages 100, 200, and 300 described with reference to FIG. 1A, FIG. 9, FIG. 16 and the like may be applied to the plurality of light sources 1105.

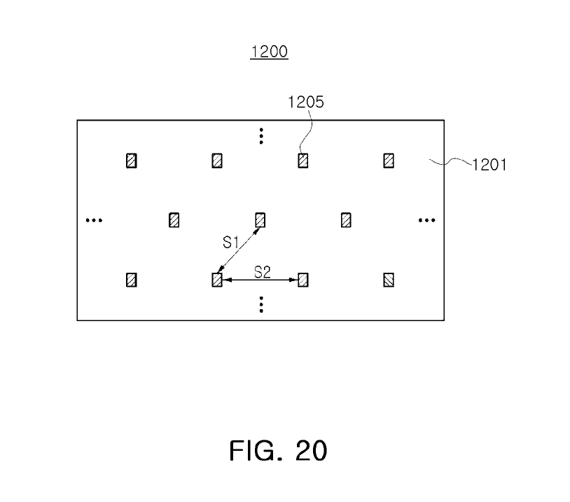

FIG. 20 is a view illustrating an exemplary disposition of light sources in the direct type backlight unit.

A direct type backlight unit 1200 according to the exemplary embodiment may include a plurality of light sources 1205 arranged on a board 1201.

The arrangement of the light sources 1205 is a matrix structure in which the light sources 1205 are arranged in rows and columns, and the rows and columns have a zigzag form. In this structure, a second matrix having the same form as that of a first matrix is disposed within the first matrix. Within each of the first and second matrices, the plurality of light sources 1205 are arranged in rows and columns in straight lines, and each light source 1205 of the second matrix is positioned within a quadrangle formed by four adjacent light sources 1205 of the first matrix.

However, in the direct type backlight unit 1200 according to the exemplary embodiment illustrated in FIG. 20, in order to enhance uniformity of brightness and light efficiency, if necessary, the first and second matrices may have different dispositions of light sources 1205 (e.g., in terms of structures, intervals, etc.). Also, in addition to the method of disposing the plurality of light sources, distances S1 and S2 between adjacent light sources may be optimized to secure uniformity of brightness.

In this manner, since the rows and columns of the light sources 1205 are disposed in a zigzag manner, rather than being disposed in straight lines, the number of light sources 1205 may be reduced by about 15% to 25% in comparison with a backlight unit having the same light emitting area.

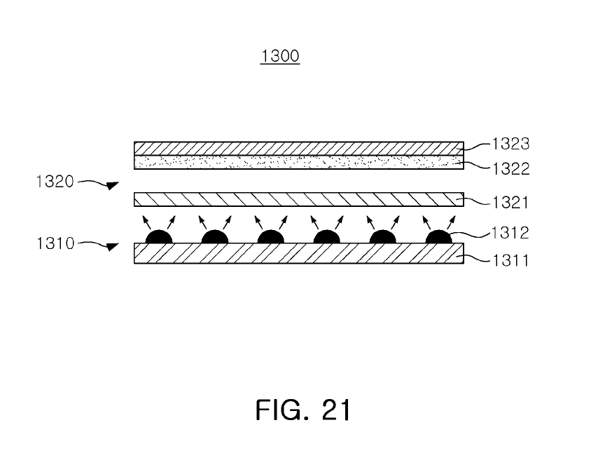

FIG. 21 is a view illustrating another embodiment of a direct type backlight unit.

Referring to FIG. 21, a backlight unit 1300 according to the exemplary embodiment may include an optical sheet 1320 and a light source module 1310 arranged below the optical sheet 1320.

The optical sheet 1320 may include a diffusion sheet 1321, a light collecting sheet 1322, a protective sheet 1323, and the like.

The light source module 1310 may include a circuit board 1311 and a plurality of light source units 1312 mounted on the circuit board 1311. The plurality of light source units 1312 may include light sources such as the light emitting device packages 100, 200, and 300 according to the embodiments illustrated in FIG. 1A, FIG. 9, and FIG. 16, and optical elements disposed on the light sources.

The optical elements may adjust a beam angle of light through refraction, and in particular, a wide beam angle lens diffusing light from the light source units 1312 to a wide region may be mainly used as the optical elements. Since the light source units 1312 with the optical elements attached thereto may have wider light distribution, and thus, when the light source module is used in a backlight, a planar lighting, and the like, the number of light sources 1312 per unit area may be reduced.

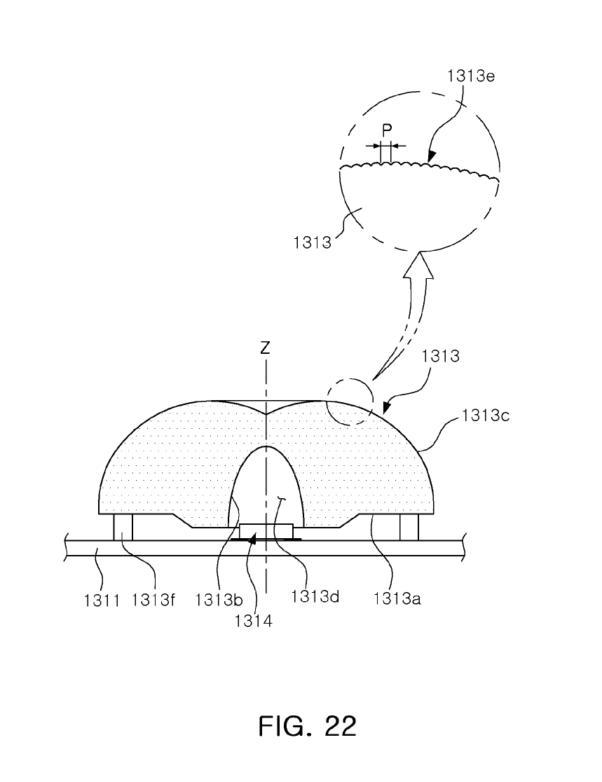

FIG. 22 is an exploded view illustrating the light source unit 1312 illustrated in FIG. 21.

Referring to FIG. 22, each of the plurality of light source units 1312 may include a light source 1314 including the light emitting device package 100, 200, or 300 and an optical element 1313. The optical element 1313 may include a bottom surface 1313a disposed on the light source 1314, an incident surface 1313b to which light from the light source 1314 is incident, and an output surface 1313c from which light is emitted outwardly.

The bottom surface 1313a may have a recess portion 1313d formed in the center through which an optical axis Z of the light source 1314 passes, and may be depressed in a direction toward the output surface 1313c. A surface of the recess portion 1313d may be defined as the incident surface 1313b to which light from the light source 1314 is incident. That is, the incident surface 1313b may form the surface of the recess portion 1313d.

A central region of the bottom surface 1313a connected to the incident surface 1313b partially protrudes to the light source 1314, thereby forming an overall non-flat structure. That is, unlike a general structure in which the entirety of the bottom surface 1313a is flat, the bottom surface 1313a has a structure in which portions thereof protrude along the circumference of the recess portion 1313d. A plurality of support portions 1313f may be provided on the bottom surface 1313a in order to fixedly support the optical element 1313 when the optical element 1313 is mounted on the circuit board 1311.

The output surface 1313c protrudes to have a dome shape in an upward direction (a light output direction) from the edge connected to the bottom surface 1313a, and the center of the output surface 1313c through which the optical axis Z passes is depressed to be concave toward the recess portion 1313d, having a point of inflection.

A plurality of protuberances and depressions 1313e may be periodically arranged in a direction from the optical axis Z toward the edge. The horizontal cross-section of each of the plurality of protuberances and depressions 1313e may be annular in shape, and may form concentric circles centered on the optical axis Z. The plurality of protuberances and depressions 1313e may be periodically arranged to spread out radially along the output surface 1313c from the optical axis Z.

The plurality of protuberances and depressions 1313e may be spaced apart by a predetermined period (pitch) P to form patterns. In this case, the period P between the plurality of protuberances and depressions 1313e may range from 0.01 mm to 0.04 mm. The plurality of protuberances and depressions 1313e may offset a performance gap of optical elements arising from a microscopic machining error generated in a process of fabricating the optical elements, thereby enhancing uniformity of light distribution.

In some other exemplary embodiments, an optical filter layer (not shown) such as a distributed Bragg reflector (DBR) may be formed on a light-emitting structure.

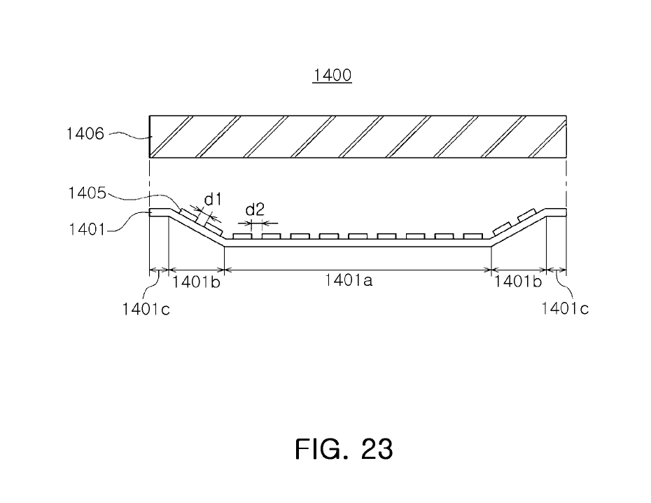

FIG. 23 is a view illustrating another embodiment of a direct type backlight unit.

Referring to FIG. 23, a backlight unit 1400 includes a light source 1405 mounted on a circuit board 1401 and at least one optical sheet 1406 disposed thereabove. The light source 1405 may include the light emitting device packages 100, 200, and 300 according to the embodiments of the present inventive concept.

The circuit board 1401 employed in the exemplary embodiment may have a first planar portion 1401a corresponding to a main region, a sloped portion 1401b disposed around the first planar portion 1401a and bent in at least a portion thereto, and a second planar portion 1401c disposed on the edge of the circuit board 1501, namely, an outer side of the sloped portion 1401b. The light sources 1405 are arranged at a first interval d1 on the first planar portion 1401a, and one or more light sources 1405 may be arranged at a second interval d2 on the sloped portion 1401b. The first interval d1 may be equal to the second interval d2. A width of the sloped portion 1401b (or a length in the cross-section) may be smaller than a width of the first planar portion 1401a and may be larger than a width of the second planar portion 1401c. Also, if necessary, at least one light source 1405 may be arranged on the second planar portion 1401c.

A slope of the sloped portion 1401b may be appropriately adjusted within a range from 0 to 90 degrees with respect to the first planar portion 1401a, and with this structure, the circuit board 1401 may maintain uniform brightness even in the vicinity of the edge of the optical sheet 1406.

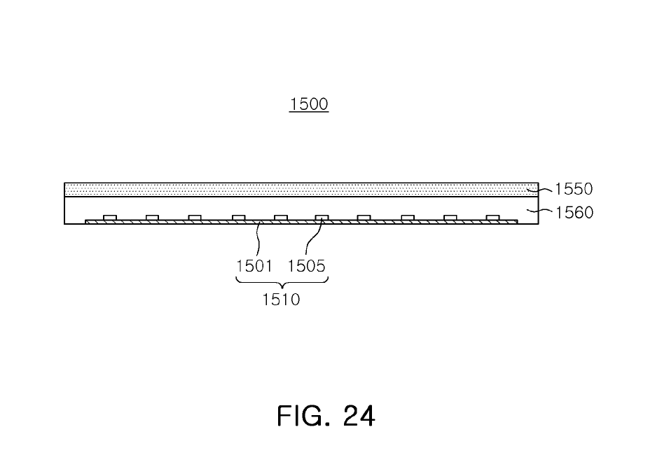

In backlight units 1500, 1600, and 1700 in FIG. 24 through FIG. 26, wavelength conversion units 1550, 1650, and 1750 are disposed outside of light sources 1505, 1605, and 1705, rather than being disposed in the light sources 1505, 1605, and 1705, to convert light, respectively.

Referring to FIG. 24, the backlight unit 1500 is a direct type backlight unit including the wavelength conversion unit 1550, a light source module 1510 arranged below the wavelength conversion unit 1550, and a bottom case 1560 accommodating the light source module 1510. Also, the light source module 1510 may include a PCB 1501 and a plurality of light sources 1505 mounted on an upper surface of the PCB 1501. The light sources 1505 may include at least one of the light emitting device packages 100, 200, and 300 according to the embodiments illustrated in FIG. 1A, FIG. 9, and FIG. 16.

In the backlight unit 1500 according to the exemplary embodiment, the wavelength conversion unit 1550 may be disposed above the bottom case 1560. Thus, at least a partial amount of light emitted from the light source module 1510 may be wavelength-converted by the wavelength conversion unit 1550. The wavelength conversion unit 1550 may be manufactured as a separate film and applied to the backlight unit 1500 in a film form, or alternatively, the wavelength conversion unit 1550 may be integrally combined with a light diffuser (not shown) so as to be provided.

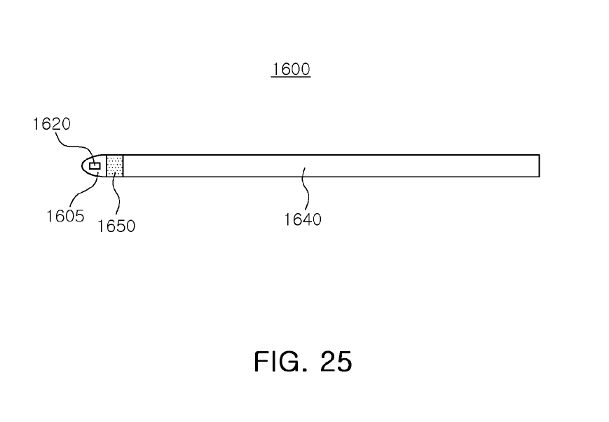

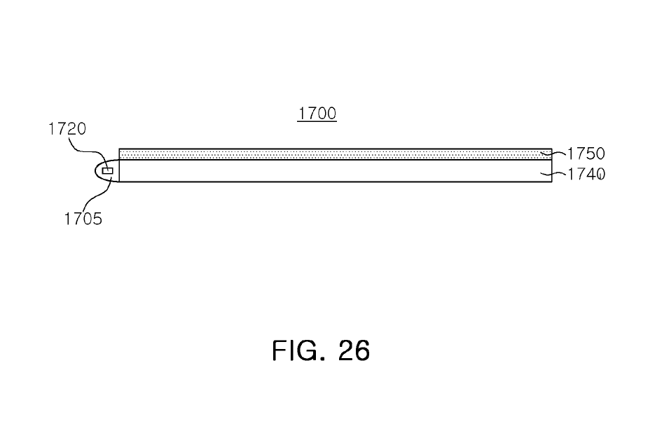

Referring to FIGS. 25 and 26, backlight units 1600 and 1700 are edge type backlight units, respectively including wavelength conversion units 1650 and 1750, light guide plates 1640 and 1740, and reflective units 1620 and 1720 and light sources 1605 and 1705 disposed on one side of the light guide plates 1640 and 1740.

Light emitted from the light sources 1605 and 1705 may be guided to the interior of the light guide plates 1640 and 1740 by the reflective units 1620 and 1720, respectively. In the backlight unit 1600 of FIG. 25, the wavelength conversion unit 1650 may be disposed between the light guide plate 1640 and the light source 1605. In the backlight unit 1700 of FIG. 26, the wavelength conversion unit 1750 may be disposed on a light emitting surface of the light guide plate 1740.

In FIG. 24 through FIG. 26, the wavelength conversion units 1550, 1650, and 1750 may include a general phosphor. In particular, in the case of using a quantum dot phosphor, the structures of wavelength conversion units 1550, 1650, and 1750 illustrated in FIG. 24 through FIG. 26 may be utilized in the backlight units 1500, 1600, and 1700 in order to compensate for the vulnerability of the quantum dot phosphor to heat or moisture from a light source.

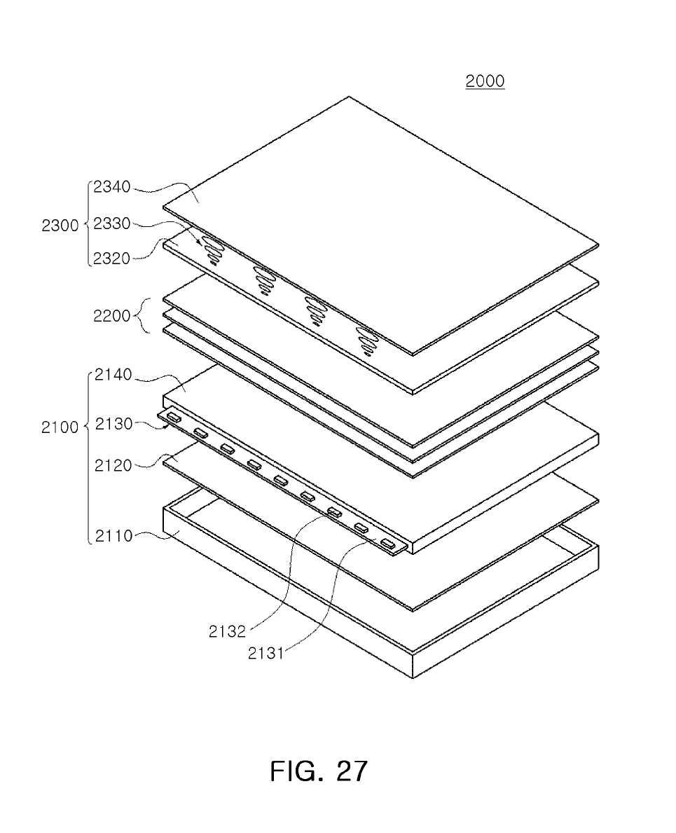

FIG. 27 is a schematic, exploded perspective view of a display device including the light emitting device package according to an exemplary embodiment of the present inventive concept.

Referring to FIG. 27, a display device 2000 may include a backlight unit 2100, an optical sheet 2200, and an image display panel 2300 such as a liquid crystal panel.

The backlight unit 2100 may include a bottom case 2110, a reflective plate 2120, a light guide plate 2140, and a light source module 2130 provided on at least one side of the light guide plate 2140. The light source module 2130 may include a PCB 2131 and light sources 2132. In particular, the light sources 2132 may include the light emitting device packages 100, 200, and 300 described with reference to FIG. 1A, FIG. 9, and FIG. 16.

The optical sheet 2200 may be disposed between the light guide plate 2140 and the image display panel 2300 and may include various types of sheets such as a diffusion sheet, a prism sheet, and a protective sheet.

The image display panel 2300 may display an image using light output from the optical sheet 2200. The image display panel 2300 may include an array substrate 2220, a liquid crystal layer 2330, and a color filter substrate 2340. The array substrate 2320 may include pixel electrodes disposed in a matrix form, thin film transistors (TFTs) applying a driving voltage to the pixel electrodes, and signal lines operating the TFTs. The color filter substrate 2340 may include a transparent substrate, a color filter, and a common electrode. The color filter may include filters allowing light having a particular wavelength, included in white light emitted from the backlight unit 2100, to selectively pass therethrough. Liquid crystals in the liquid crystal layer 2330 are rearranged by an electric field applied between the pixel electrodes and the common electrode, and thereby light transmittance is adjusted. The light with transmittance thereof adjusted may pass through the color filter of the color filter substrate 2340, thus displaying an image. The image display panel 2300 may further include a driving circuit unit processing an image signal, or the like.

The display device 2000 according to the exemplary embodiment uses the light sources 2132 emitting blue light, green light, and red light having a relatively small FWHM. Thus, emitted light, after passing through the color filter substrate 2340, may implement blue, green, and red having a high level of color purity.

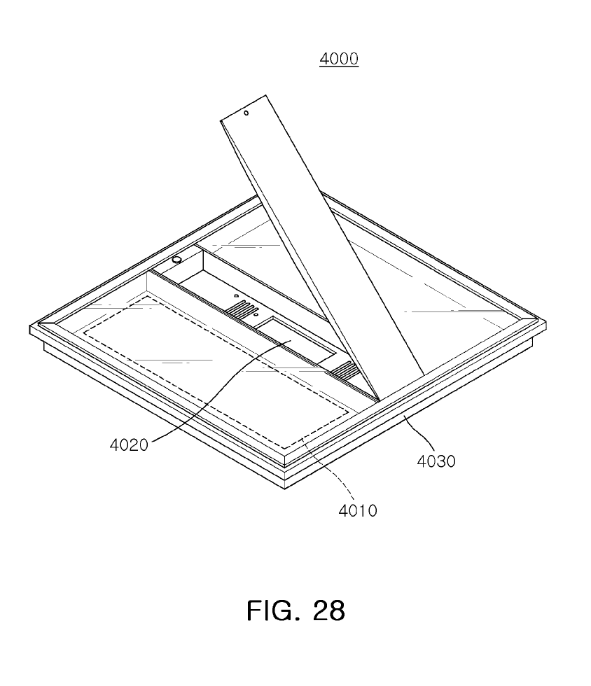

FIG. 28 through FIG. 31 are views illustrating lighting devices including the light emitting device package according to an exemplary embodiment of the present inventive concept.

Referring to FIG. 28, a planar type lighting device 4000 may include alight source module 4010, a power supply device 4020, and a housing 4030. According to an exemplary embodiment of the present inventive concept, the light source module 4010 may include a light emitting device array as alight source, and the power supply device 4020 may include a light emitting device driving unit.

The light source module 4010 may include a light emitting device array and may be formed to have an overall planar shape. According to an exemplary embodiment of the present inventive concept, the light emitting device array may include a light emitting device and a controller storing driving information of the light emitting device. The light emitting device array may include a plurality of light emitting device packages connected to each other in series or in parallel. In an exemplary embodiment, at least one of the light emitting device packages 100, 200, and 300 described with reference to FIG. 1A, FIG. 9, and FIG. 16 may be applied.

The power supply device 4020 may be configured to supply power to the light source module 4010. The housing 4030 may have an accommodation space accommodating the light source module 4010 and the power supply device 4020 therein and have a hexahedral shape with one side thereof open, but the shape of the housing 4030 is not limited thereto. The light source module 4010 may be disposed to emit light to the open side of the housing 4030.

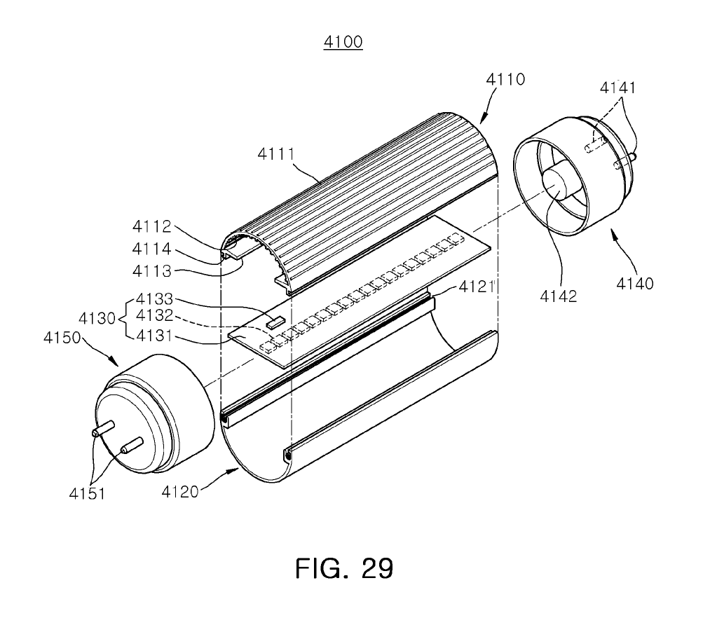

FIG. 29 is an exploded perspective view schematically illustrating a bar type lamp as a lighting device according to an exemplary embodiment of the present inventive concept.

In detail, a lighting device 4100 includes a heat dissipation member 4110, a cover 4120, a light source module 4130, a first socket 4140, and a second socket 4150. A plurality of heat dissipation fins 4111 and 4112 may be formed in a concavo-convex pattern on an internal or/and external surface of the heat dissipation member 4110, and the heat dissipation fins 4111 and 4112 may be designed to have various shapes and intervals (spaces) therebetween. A support 4113 having a protruded shape may be formed on an inner side of the heat dissipation member 4110. The light source module 4130 may be fixed to the support 4113. Stoppage protrusions 4114 may be formed on both ends of the heat dissipation member 4110.

The stoppage recesses 4121 may be formed in the cover 4120, and the stoppage protrusions 4114 of the heat dissipation member 4110 may be coupled to the stoppage recesses 4121. The positions of the stoppage recesses 4121 and the stoppage protrusions 4114 may be interchanged.

The light source module 4130 may include a light emitting device array. The light source module 4130 may include a PCB 4131, a light source 4132, and a controller 4133. As described above, the controller 4133 may store driving information of the light source 4132. Circuit wirings are formed on the PCB 4131 to operate the light source 4132. Also, components for operating the light source 4132 may be provided.

The first and second sockets 4140 and 4150, a pair of sockets, are respectively coupled to opposing ends of the cylindrical cover unit including the heat dissipation member 4110 and the cover 4120. For example, the first socket 4140 may include electrode terminals 4141 and a power source device 4142, and dummy terminals 4151 may be disposed on the second socket 4150. Also, an optical sensor and/or a communications module may be installed in either the first socket 4140 or the second socket 4150. For example, the optical sensor and/or the communications module may be installed in the second socket 4150 in which the dummy terminals 4151 are disposed. In another example, the optical sensor and/or the communications module may be installed in the first socket 4140 in which the electrode terminals 4141 are disposed.

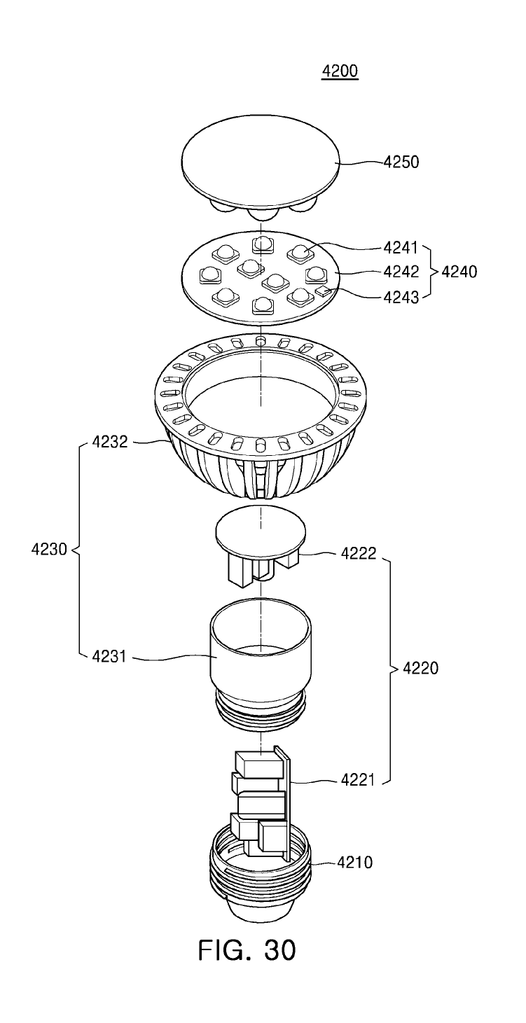

FIG. 30 is an exploded perspective view schematically illustrating a bulb type lamp as a lighting device according to an exemplary embodiment of the present inventive concept.

In detail, a lighting device 4200 may include a socket 4210, a power source unit 4220, a heat dissipation unit 4230, a light source module 4240, and an optical unit 4250. According to an exemplary embodiment of the present inventive concept, the light source module 4240 may include a light emitting device array, and the power source unit 4220 may include a light emitting device driving unit.

The socket 4210 may be configured to be replaced with an existing lighting device. Power supplied to the lighting device 4200 may be applied through the socket 4210. As illustrated, the power source unit 4220 may include a first power source unit 4221 and a second power source unit 4222. The first power source unit 4221 and the second power source unit 4222 may be assembled to form the power source unit 4220. The heat dissipation unit 4230 may include an internal heat dissipation unit 4231 and an external heat dissipation unit 4232. The internal heat dissipation unit 4231 may be directly connected to the light source module 4240 and/or the power source unit 4220 to transmit heat to the external heat dissipation unit 4232. The optical unit 4250 may include an internal optical unit (not shown) and an external optical unit (not shown) and may be configured to evenly distribute light emitted from the light source module 4240.

The light source module 4240 may emit light to the optical unit 4250 upon receiving power from the power source unit 4220. The light source module 4240 may include one or more light emitting devices 4241, a circuit board 4242, and a controller 4243. The controller 4243 may store driving information of the light emitting devices 4241.

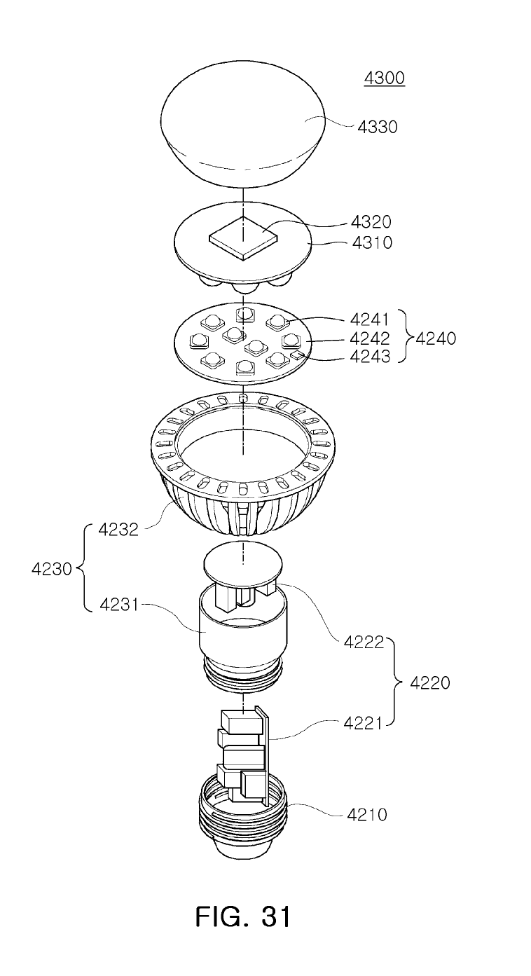

FIG. 31 is an exploded perspective view schematically illustrating a lamp, including a communications module, as a lighting device, according to an exemplary embodiment of the present inventive concept.

In detail, a lighting device 4300 according to the present exemplary embodiment is different from the lighting device 4200 illustrated in FIG. 30, in that a reflective plate 4310 is provided above the light source module 4240, and here, the reflective plate 4310 serves to allow light from the light source to spread evenly in a direction toward the lateral side and back side thereof, and thereby glare may be reduced.

A communications module 4320 may be mounted on an upper portion of the reflective plate 4310, and home network communication may be realized through the communications module 4320. For example, the communications module 4320 may be a wireless communications module using ZigBee, Wi-Fi, or light fidelity (Li-Fi), and may control lighting installed within or outside of a household, such as turning on or off a lighting device, adjusting brightness of a lighting device, and the like, through a smartphone or a wireless controller. Also, home appliances or an automobile system within or outside of a household, such as a TV, a refrigerator, an air-conditioner, a door lock, or automobiles, and the like, may be controlled through a Li-Fi communications module using visible wavelengths of the lighting device installed within or outside of the household.

The reflective plate 4310 and the communications module 4320 may be covered by a cover unit 4330.

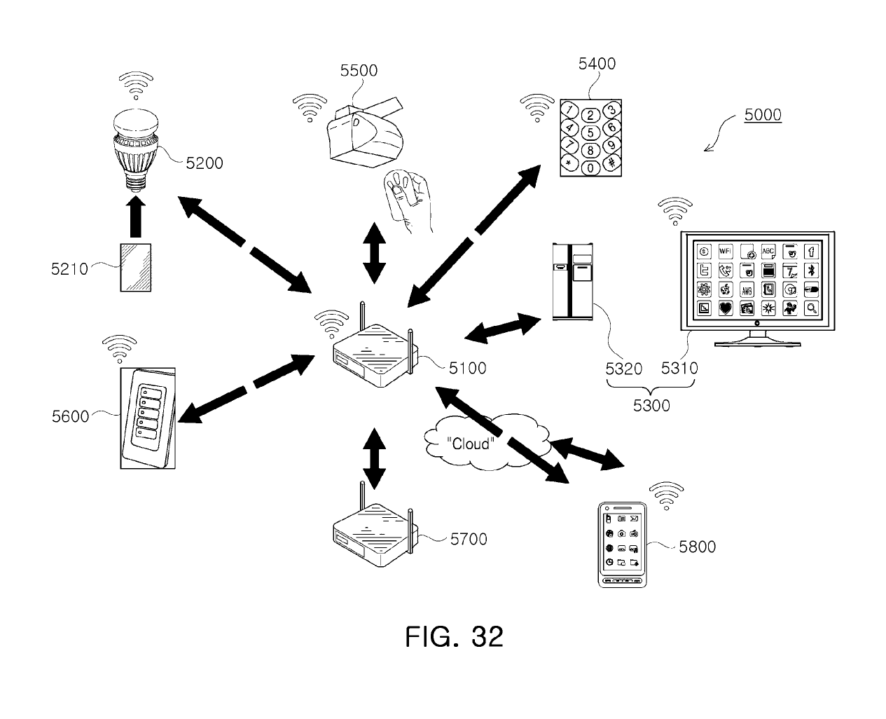

FIG. 32 through FIG. 34 are schematic views, each illustrating a network system according to an exemplary embodiment of the present inventive concept.

FIG. 32 is a view schematically illustrating an indoor lighting control network system. A network system 5000 may be a complex smart lighting-network system combining a lighting technology using a light emitting device such as an LED, or the like, Internet of things (IoT) technology, a wireless communications technology, and the like. The network system 5000 may be realized using various lighting devices and wired/wireless communications devices, and may be realized by a sensor, a controller, a communications unit, software for network control and maintenance, and the like.

The network system 5000 may be applied even to an open space such as a park or a street, as well as to a closed space such as a house or an office. The network system 5000 may be realized on the basis of the IoT environment in order to collect and process a variety of information and provide the same to users. Here, an LED lamp 5200 included in the network system 5000 may serve not only to receive information regarding a surrounding environment from a gateway 5100 and control lighting of the LED lamp 5200 itself, but also to check and control operational states of other devices 5300 to 5800 included in the IoT environment on the basis of a function such as visible light communications, or the like, of the LED lamp 5200.

Referring to FIG. 32, the network system 5000 may include the gateway 5100 processing data transmitted and received according to different communications protocols, the LED lamp 5200 connected to be available for communicating with the gateway 5100 and including an LED light emitting device, and a plurality of devices 5300 to 5800 connected to be available for communicating with the gateway 5100 according to various wireless communications schemes. In order to realize the network system 5000 on the basis of the IoT environment, each of the devices 5300 to 5800, as well as the LED lamp 5200, may include at least one communications module. In an exemplary embodiment, the LED lamp 5200 may be connected to be available for communicating with the gateway 5100 according to wireless communication protocols such as Wi-Fi, ZigBee, or Li-Fi, and to this end, the LED lamp 5200 may include at least one communications module 5210 for a lamp.

As mentioned above, the network system 5000 may be applied even to an open space such as a park or a street, as well as to a closed space such as a house or an office. When the network system 5000 is applied to a house, the plurality of devices 5300 to 5800 included in the network system and connected to be available for communicating with the gateway 5100 on the basis of the IoT technology may include a home appliance 5300, a digital door lock 5400, a garage door lock 5500, a light switch 5600 installed on a wall, or the like, a router 5700 for relaying a wireless communication network, and a mobile device 5800 such as a smartphone, a tablet, or a laptop computer.

In the network system 5000, the LED lamp 5200 may check operational states of various devices 5300 to 5800 using the wireless communications network (ZigBee, Wi-Fi, LI-Fi, etc.) installed in a household or automatically control illumination of the LED lamp 5200 itself according to a surrounding environment or situation. Also, the devices 5300 to 5800 included in the network system 5000 may be controlled using Li-Fi communications using visible light emitted from the LED lamp 5200.

First, the LED lamp 5200 may automatically adjust illumination of the LED lamp 5200 on the basis of information of a surrounding environment transmitted from the gateway 5100 through the communications module 5210 for a lamp or information of a surrounding environment collected from a sensor installed in the LED lamp 5200. For example, brightness of illumination of the LED lamp 5200 may be automatically adjusted according to types of programs broadcast on the TV 5310 or brightness of a screen. To this end, the LED lamp 5200 may receive operation information of the TV 5310 from the communications module 5210 for a lamp connected to the gateway 5100. The communications module 5210 for a lamp may be integrally modularized with a sensor and/or a controller included in the LED lamp 5200.

For example, when a program value broadcast in a TV program is a human drama, a color temperature of illumination may be decreased to be 12000K or lower, for example, to 5000K, and a color tone may be adjusted according to preset values, and thereby a cozy atmosphere is presented. Conversely, when a program value is a comedy program, the network system 5000 may be configured so that a color temperature of illumination is increased to 5000K or higher according to a preset value, and illumination is adjusted to white illumination based on a blue color.

Also, when there is no one at home, and a predetermined time has lapsed after digital door lock 5400 is locked, all of the turned-on LED lamps 5200 are turned off to prevent a waste of electricity. Also, when a security mode is set through the mobile device 5800, or the like, and the digital door lock 5400 is locked with no one at home the LED lamp 5200 may be maintained in a turned-on state.

An operation of the LED lamp 5200 may be controlled according to surrounding environments collected through various sensors connected to the network system 5000. For example, when the network system 5000 is realized in a building, a lighting, a position sensor, and a communications module are combined in the building, and position information of people in the building is collected and the lighting is turned on or turned off, or the collected information may be provided in real time to effectively manage facilities or effectively utilize an idle space. In general, a lighting device such as the LED lamp 5200 is disposed in almost every space of each floor of a building, and thus, various types of information of the building may be collected through a sensor integrally provided with the LED lamp 5200 and used for managing facilities and utilizing an idle space.

On the other hand, the LED lamp 5200 may be combined with an image sensor, a storage device, and the communications module 5210 for a lamp, to be utilized as a device for maintaining building security, or sensing and coping with an emergency situation. For example, when a sensor of smoke or temperature, or the like, is attached to the LED lamp 5200, a fire may be promptly sensed to minimize damage. Also, brightness of lighting may be adjusted in consideration of outside weather or an amount of sunshine, thereby saving energy and providing an agreeable illumination environment.

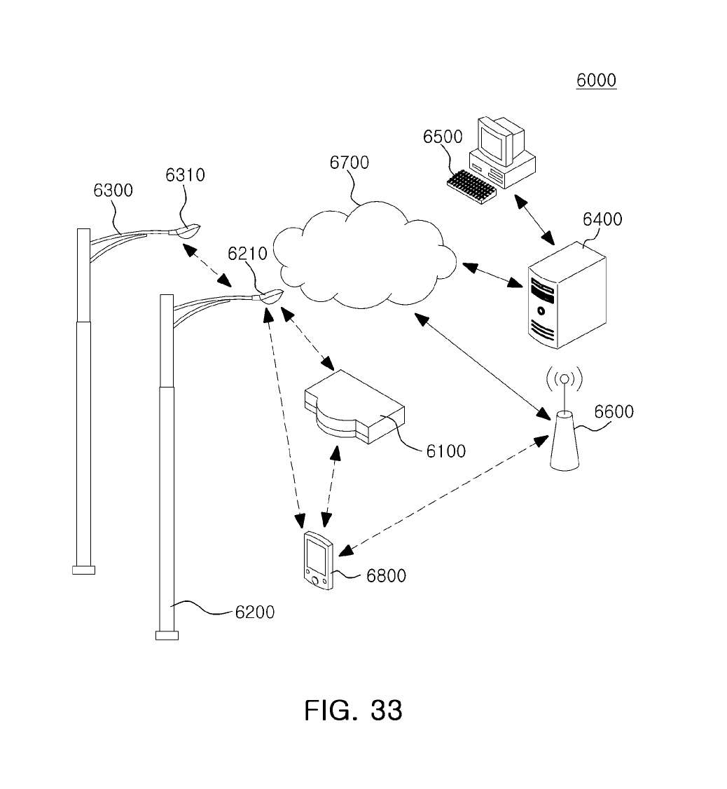

As described above, the network system 5000 may also be applied to an open space such as a street or a park, as well as to a closed space such as a house, an office, or a building. When the network system 5000 is intended to be applied to an open space without a physical limitation, it may be difficult to realize the network system 5000 due to a limitation in a distance of wireless communications or communications interference due to various obstacles. In this case, a sensor, a communications module, and the like, may be installed in each lighting fixture, and each lighting fixture may be used as an information collecting means or a communications relay means, whereby the network system 5000 may be more effectively realized in an open environment. This will hereinafter be described with reference to FIG. 33.

FIG. 33 is a view illustrating an embodiment of a network system 6000 applied to an open space. Referring to FIG. 33, a network system 6000 according to the present exemplary embodiment may include a communications connection device 6100, a plurality of lighting fixtures 6200 and 6300 installed at every predetermined interval and connected to be available for communicating with the communications connection device 6100, a server 6400, a computer 6500 managing the server 6400, a communications base station 6600, a communications network 6700, a mobile device 6800, and the like.

Each of the plurality of lighting fixtures 6200 and 6300 installed in an open outer space such as a street or a park may include smart engines 6210 and 6310, respectively. The smart engines 6210 and 6310 may include alight emitting device, a driver of the light emitting device, a sensor collecting information of a surrounding environment, a communications module, and the like. The smart engines 6210 and 6310 may communicate with other neighboring equipment by means of the communications module according to communications protocols such as Wi-Fi, ZigBee, and Li-Fi.

For example, one smart engine 6210 may be connected to communicate with another smart engine 6310. Here, a Wi-Fi extending technique (Wi-Fi mesh) may be applied to communications between the smart engines 6210 and 6310. The at least one smart engine 6210 may be connected to the communication connection device 6100 connected to the communications network 6700 by wired/wireless communications. In order to increase communication efficiency, some smart engines 6210 and 6310 may be grouped and connected to the single communications connection device 6100.

The communications connection device 6100 may be an access point (AP) available for wired/wireless communications, which may relay communications between the communications network 6700 and other equipment. The communications connection device 6100 may be connected to the communications network 6700 in either a wired manner or a wireless manner, and for example, the communications connection device 6100 may be mechanically received in any one of the lighting fixtures 6200 and 6300.

The communications connection device 6100 may be connected to the mobile device 6800 through a communications protocol such as Wi-Fi, or the like. A user of the mobile device 6800 may receive surrounding environment information collected by the plurality of smart engines 6210 and 6310 through the communications connection device 6100 connected to the smart engine 6210 of the lighting fixture 6200 adjacent to the mobile device 6800. The surrounding environment information may include nearby traffic information, weather information, and the like. The mobile device 6800 may be connected to the communications network 6700 according to a wireless cellular communications scheme such as 3G or 4G through the communications base station 6600.

Meanwhile, the server 6400 connected to the communications network 6700 may receive information collected by the smart engines 6210 and 6310 respectively installed in the lighting fixtures 6200 and 6300 and monitor an operational state, or the like, of each of the lighting fixtures 6200 and 6300. In order to manage the lighting fixtures 6200 and 6300 on the basis of the monitoring results of the operational states of the lighting fixtures 6200 and 6300, the server 6400 may be connected to the computer 6500 providing a management system. The computer 6500 may execute software, or the like, capable of monitoring and managing operational states of the lighting fixtures 6200 and 6300, specifically, the smart engines 6210 and 6310.

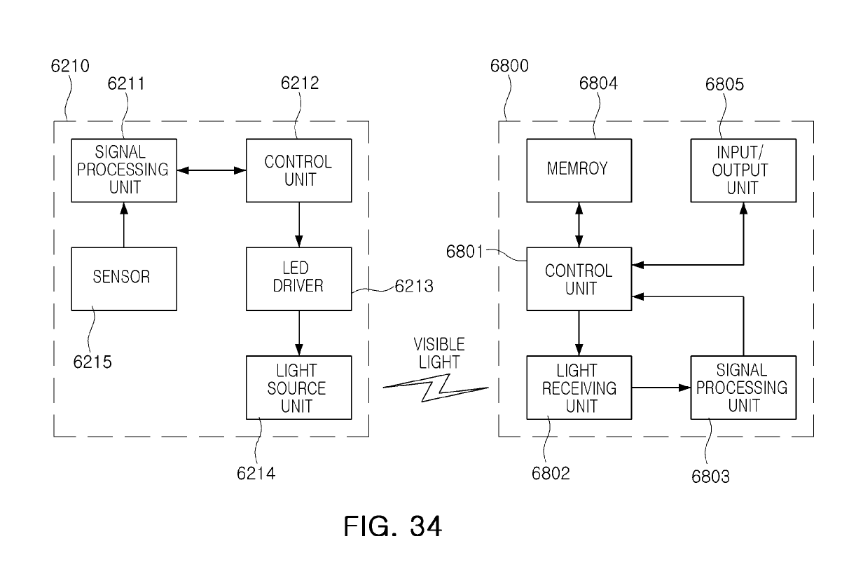

In order to transmit information collected by the smart engines 6210 and 6310 to the mobile device 6800 of the user, various communications schemes may be applied. Referring to FIG. 33, information collected by the smart engines 6210 and 6310 may be transmitted to the mobile device 6800 through the communications connection device 6100 connected to the smart engines 6210 and 6310, or the smart engines 6210 and 6310 and the mobile device 6800 may be connected to directly communicate with each other. The smart engines 6210 and 6310 and the mobile device 6800 may directly communicate with each other by visible light communications (Li-Fi). This will hereinafter be described with reference to FIG. 34.

FIG. 34 is a block diagram illustrating a communications operation between the smart engine 6210 of the lighting fixture 6200 and the mobile device 6800 according to visible light communications. Referring to FIG. 34, the smart engine 6210 may include a signal processing unit 6211, a control unit 6212, an LED driver 6213, a light source unit 6214, a sensor 6215, and the like. The mobile device 6800 connected to the smart engine 6210 by visible light communications may include a control unit 6801, a light receiving unit 6802, a signal processing unit 6803, a memory 6804, an input/output unit 6805, and the like.

The visible light communications (VLC) technology (or light fidelity (Li-Fi)) is a wireless communications technology transferring information wirelessly by using light having a visible light wavelength band recognizable to the naked eye. The visible light communications technology is distinguished from the existing wired optical communications technology and the infrared data association (IrDA) in that it uses light having a visible light wavelength band, namely, a particular visible light frequency from the light emitting device package according to the exemplary embodiment described above and is distinguished from the existing wired optical communications technology in that a communications environment is based on a wireless scheme. Also, unlike RF wireless communications, the VLC technology (or Li-Fi) has excellent convenience because it can be used without being regulated or authorized in the aspect of frequency usage, and VLC technology (or Li-Fi) has a distinction of having excellent physical security and a user's verification of a communication link with his or her own eyes. Most of all, VLC technology (or Li-Fi) is differentiated in that it has features as a convergence technology that obtains both a unique purpose as a light source and a communications function.

Referring to FIG. 34, the signal processing unit 6211 of the smart engine 6210 may process data intended to be transmitted and received by VLC. In an exemplary embodiment, the signal processing unit 6211 may process information collected by the sensor 6215 into data and transmit the processed data to the control unit 6212. The control unit 6212 may control operations of the signal processing unit 6211, the LED driver 6213, and the like, and in particular, the control unit 6212 may control an operation of the LED driver 6213 on the basis of data transmitted from the signal processing unit 6211. The LED driver 6213 drives the light source unit 6214 according to a control signal transmitted from the control unit 6212, thereby transmitting data to the mobile device 6800.

The mobile device 6800 may include the light receiving unit 6802 for recognizing visible light including data, in addition to the control unit 6801, the memory 6804 storing data, the input/output unit 6805 including a display, a touch screen, an audio output unit, and the like, and the signal processing unit 6803. The light receiving unit 6802 may sense visible light and convert the sensed visible light into an electrical signal, and the signal processing unit 6803 may decode data included in the electrical signal converted by the light receiving unit 6802. The control unit 6801 may store the data decoded by the signal processing unit 6803 in the memory 6804 or may output the decoded data through the input/output unit 6805 to allow the user to recognize the data.

As set forth above, according to exemplary embodiments of the present inventive concept, an area of the reflective metal layer included in the light emitting device package may be significantly increased, whereby light extraction efficiency may be increased and at the same time, an undercut defect that may occur in a process of forming the first and second electrodes applying an electrical signal to the light emitting device may be solved. In addition, a manufacturing cost required in a process of forming an underfill resin filling a space between the package substrate and the light emitting device may be reduced.

While exemplary embodiments have been shown and described above, it will be apparent to those skilled in the art that modifications and variations could be made without departing from the scope of the invention as defined by the appended claims.

1. A light emitting device package comprising:
a light emitting device including a substrate and a light emitting structure including a first conductivity type semiconductor layer, an active layer, and a second conductivity type semiconductor layer, stacked on the substrate;
a reflective conductive layer provided on the light emitting structure,
an insulation layer comprising a first insulating layer and a second insulating layer, the insulation layer substantially surrounding the reflective conductive layer in cross-section;
a first electrode overlying the insulation layer and electrically connected to the first conductivity type semiconductor layer; and
a second electrode overlying the insulation layer and electrically connected to the second conductivity type semiconductor layer,
wherein the first and second electrodes are spaced apart from each other, the first and second electrodes defining a first opening therebetween.

2. The light emitting device package of claim 1, wherein the first electrode is electrically connected to the first conductivity type semiconductor layer through a second opening formed through the reflective conductive layer.

3. The light emitting device package of claim 2, wherein the second opening is disposed in a lower portion of the first electrode.

4. The light emitting device package of claim 1, wherein the second electrode is electrically connected to the second conductivity type semiconductor layer through a third opening formed through the reflective conductive layer.

5. The light emitting device package of claim 4, wherein the third opening is disposed in a lower portion of the second electrode.

6. The light emitting device package of claim 1, wherein a portion of the reflective conductive layer extends between the first and second electrodes.

7. The light emitting device package of claim 1, wherein an end portion of the insulation layer protrudes away from a sidewall of the first or second electrode towards an outside of the first or second electrode.

8. The light emitting device package of claim 1, wherein the first insulting layer is disposed between the light emitting device and the reflective conductive layer; and
wherein the second insulating layer is disposed between the reflective conductive layer and at least one of the first and second electrodes.

9. The light emitting device package of claim 8, wherein the first electrode and the second electrode penetrate through the insulation layer.

10. (canceled)

11. The light emitting device package of claim 1, wherein the light emitting device further includes a first contact electrode connected to the first conductivity type semiconductor layer and a second contact electrode connected to the second conductivity type semiconductor layer, and
wherein the first electrode and the second electrode are connected to the first contact electrode and the second contact electrode, respectively.

12. The light emitting device package of claim 1, wherein at least one of the first electrode and the second electrode includes:
a first layer provided on the reflective conductive layer; and
a second layer provided on the first layer, and having a thickness greater than a thickness of the first layer.

13. (canceled)

14. A light emitting device package comprising:
a light emitting device including a substrate and a light emitting structure including a first conductivity type semiconductor layer, an active layer, and a second conductivity type semiconductor layer, stacked on the substrate;
a first electrode electrically connected to the first conductivity type semiconductor layer;
a second electrode electrically connected to the second conductivity type semiconductor layer and separated from the first electrode; and
a reflective conductive layer disposed between the light emitting structure and the first and second electrodes, electrically isolated from the light emitting device and the first and second electrodes,
wherein a portion of the reflective conductive layer is not overlapped by the first or second electrodes.

15. (canceled)

16. The light emitting device package of claim 14, wherein the first and second electrodes are spaced apart from each other, defining a first opening therebetween, and
wherein at least a portion of the reflective conductive layer is absent in a plurality of other regions different from the first opening to form second and third openings that extend through the reflective conductive layer.

17. The light emitting device package of claim 16, wherein an area of the first opening is greater than a total area of the second and third openings in plan view.

18. The light emitting device package of claim 16, wherein the first electrode and the second electrode extend through the second and third openings in the reflective conductive layer, respectively, to be electrically connected to the first conductivity type semiconductor layer and the second conductivity type semiconductor layer, respectively.

19. The light emitting device package of claim 16, further comprising: an insulation layer surrounding the reflective conductive layer in cross-section.

20. (canceled)

21. (canceled)

22. A light emitting device package comprising:
a light emitting device including a substrate and a light emitting structure including a first conductivity type semiconductor layer, an active layer, and a second conductivity type semiconductor layer, stacked on the substrate;
a first insulating layer overlying the light emitting structure;
a reflective conductive layer overlying the first insulating layer;
a second insulating layer overlying the reflective conductive layer;
first and second electrodes overlying the second insulating layer, the first and second electrodes spaced apart from each other and defining a first opening therebetween,
wherein the first electrode is electrically connected to the first conductivity type semiconductor layer through a second opening defined through the reflective conductive layer and formed under the first electrode, and
wherein the second electrode is electrically connected to the second conductivity type semiconductor layer through a third opening defined through the reflective conductive layer and formed under the second electrode.

23. The device package of claim 22, wherein the reflective conductive layer extends below and between the first and second electrodes.

24. The device package of claim 22, wherein the reflective conductive layer is electrically isolated from the first and second electrodes.

25. The device package of claim 22, wherein the first and second insulating layer collectively form an insulation layer, the first electrode is electrically insulated from the reflective conductive layer at least by a portion of the insulation layer formed in the second opening and the second electrode is electrically insulated from the reflective conductive layer at least by a portion of the insulation layer formed in the third opening.

26-34. (canceled)
